(19) United States
(12) Patent Application Publication
(10) Pub. No.: US 2026/0143703 A1
(43) Pub. Date: May 21, 2026

(54) THREE-DIMENSIONAL MEMORY DEVICES AND FABRICATING METHODS THEREOF

(71) Applicant: Yangtze Memory Technologies Co., Ltd., Wuhan (CN)

(72) Inventors: Linchun Wu, Wuhan (CN); Di Wang, Wuhan (CN); Dingding Shen, Wuhan (CN); Kun Zhang, Wuhan (CN); Wenxi Zhou, Wuhan (CN)

(21) Appl. No.: 19/011,406

(22) Filed: Jan. 6, 2025

Related U.S. Application Data
(63) Continuation of application No. PCT/CN2024/132848, filed on Nov. 19, 2024.

(51) Int. Cl. H10B 43/27; H10B 43/10

(52) U.S. Cl. CPC H10B 43/27; H10B 43/10

(57) ABSTRACT

Three-dimensional (3D) memory devices and fabricating methods thereof are disclosed. One disclosed semiconductor device comprises a stack structure comprising an array region and a contact region, and a gate line slit structure extending vertically through the stack structure and laterally along a first lateral direction to divide the stack structure into memory blocks. The gate line slit structure comprises a first dummy channel structure located at a boundary between the array region and the contact region, a first gate line slit segment extending laterally from the first dummy channel structure into the array region, and a second gate line slit segment extending laterally from the first dummy channel structure into the contact region.

### CROSS-REFERENCE TO RELATED APPLICATIONS

This application is a continuation of International Application No. PCT/CN 2024/132848, filed on Nov. 19, 2024, which is hereby incorporated by reference in its entirety.

### TECHNICAL FIELD

The present disclosure generally relates to the field of semiconductor technology, and more particularly, to three-dimensional (3D) memory devices, and fabricating methods for forming three-dimensional (3D) memory devices.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As such, memory density for planar memory cells approaches an upper limit. A three-dimensional (3D) memory architecture can address the density limitation in planar memory cells.

As semiconductor technology advances, 3D memory devices, such as 3D NAND memory devices, keep scaling more film layers to improve the area utilization of wafers. In some existing 3D NAND memory devices, as the number of film layers increases and the structure of the film layer becomes more complicated, the silicon substrate used as a carrier of the film layers may not support the wafer deformation caused by film stresses, which may eventually lead to an arcing of the wafer. Further, as the number of oxide/nitride (ON) layers increases, an etch depth of gate line slit (GLS) increases accordingly, resulting changes of the critical dimensions of the GLS, thereby increasing a risk of unstable structure due to stress and other factors. Such unstable structure may cause the memory finger crooking/collapse, wafer bow effects, and affect subsequent 3D memory device fabricating processes, such as increasing overlay error in the lithographic alignment process.

### SUMMARY

One aspect of the present disclosure provides a semiconductor device, including: a stack structure including an array region and a contact region located on a side of the array region in a first lateral direction; and a gate line slit (GLS) structure extending vertically through the stack structure and laterally along the first lateral direction. The GLS structure includes: a dielectric structure extending vertically through the stack structure and located at a boundary between the array region and the contact region; a first GLS structure segment laterally extending from the dielectric structure to the contact region along the first lateral direction; and a second GLS structure segment laterally extending from the dielectric structure to the array region along the first lateral direction, where the dielectric structure separates the first GLS structure segment and the second GLS structure segment, a first dimension of the dielectric structure in the first lateral direction is less than a second dimension of the dielectric structure in a second lateral direction perpendicular to the first lateral direction.

In some implementations, the first GLS structure segment includes a first filling wall sandwiched between first spacer layers along the second lateral direction; and the second GLS structure segment comprises a second filling wall sandwiched between second spacer layers along the second lateral direction.

In some implementations, the dielectric structure is a single oxide layer having the first dimension in the first lateral direction greater than a summation of a first thickness of the first spacer layer in the second lateral direction and a second thickness of the second spacer layer in the second lateral direction.

In some implementations, the dielectric structure is a composite structure, which includes: an intermedia sub-layer having a first material; a first spacer sub-layer between the intermedia sub-layer and the first GLS structure segment, and having a second material different from the first material but same as the first spacer layers of the first GLS structure segment; and a second spacer sub-layer between the intermedia sub-layer and the second GLS structure segment, and having a third material different from the first material but same as the second spacer layers of the second GLS structure segment.

In some implementations, the first material is an oxide material; and the second material and the third material are same and deposited on both sides of the intermedia sub-layer in the first lateral direction.

In some implementations, the intermedia sub-layer has a curved wall structure.

In some implementations, the curved wall structure is convex toward the second GLS structure segment.

In some implementations, sidewalls of the first GLS structure segment and the second GLS structure segment in second first lateral direction include curved surfaces.

In some implementations, each of the first filling wall and the second filling wall includes an upper portion and a lower portion, where a dimension of the upper portion is greater than a dimension of the lower portion along the second lateral direction.

In some implementations, the lower portion of the first filling wall includes protruding portions each having a lateral surface and a bottom surface surrounded by the first spacer layers from all lateral directions and a bottom direction; and the lower portion of the second filling wall includes protruding portions each having a lateral surface and a bottom surface surrounded by the second spacer layers from all lateral directions and a bottom direction.

In some implementations, a first height of first protruding portions of the first filling wall in a vertical direction is greater than a second height of second protruding portions of the second filling wall in the vertical direction.

In some implementations, the semiconductor device further includes a semiconductor layer located between the stack structure and a substrate. A top surface of the semiconductor layer is lower than a bottom surface of the upper portion of the first filling wall, and a bottom surface of the semiconductor layer is higher than a bottom surface of the upper portion of the second filling wall.

In some implementations, the first protruding portions and second protruding portions vertically extend into an upper portion of the substrate.

In some implementations, the semiconductor layer in the contact region includes: ends extended into the second spacer layers; and separated portions between the first protruding portions and each having a lateral surface, a bottom surface and a top surface surrounded by the first spacer layers from all lateral directions, the bottom direction and a top direction.

In some implementations, the first dimension is in a range from about 30 nm to about 200 nm, and the second dimension is in a range from about 500 nm to about 1000 nm.

In some implementations, the semiconductor device further includes: channel structures each vertically extending through the stack structure and located in the array region; and dummy channel structures each vertically extending through the stack structure and located in the contact region.

In some implementations, the stack structure in the array region includes conductive layers and first dielectric layers alternatively stacked in a vertical direction, and the stack structure in the contact region includes: a first stack portion adjacent to the first GLS structure segment and comprising the conductive layers and the first dielectric layers alternatively stacked in the vertical direction, and a second stack portion separated from the first GLS structure segment by the first stack portion, and comprising the first dielectric layers and second dielectric layers alternatively stacked in the vertical direction.

In some implementations, a first semiconductor structure comprising the stack structure and the GLS structure is bonded with a second semiconductor structure comprising a peripheral circuit.

Another aspect of the present disclosure provides a method for forming a semiconductor device, including: forming a stack structure comprising an array region and a contact region located on a side of the array region in a first lateral direction; and forming a gate line slit (GLS) structure extending vertically through the stack structure and laterally along the first lateral direction. Forming the GLS structure includes: forming a dielectric structure extending vertically through the stack structure and located at a boundary between the array region and the contact region; forming a first GLS structure segment laterally extending from the dielectric structure to the contact region along the first lateral direction; and forming a second GLS structure segment laterally extending from the dielectric structure to the array region along the first lateral direction, where the dielectric structure separates the first GLS structure segment and the second GLS structure segment, a first dimension of the dielectric structure in the first lateral direction is less than a second dimension of the dielectric structure in a second lateral direction perpendicular to the first lateral direction.

In some implementations, forming the stack structure includes: forming an insulating layer on a substrate; forming a semiconductor layer on the insulating layer; forming alternately stacked first dielectric layers and second dielectric layers along a vertical direction on the semiconductor layer; and forming an array of first through holes in the contact region and an array of second through holes in the array region, wherein each first through hole and each second through hole is vertically extending through the stack structure into the substrate.

In some implementations, forming the GLS structure includes: forming a first trench extending along the first lateral direction by etching one row of the array of first through holes; removing portions of the second dielectric layers located at the contact region through the first trench to form first gaps; filling the first trench and the first gaps with a sacrificial material; forming a second trench extending along the first lateral direction by etching one row of the array of second through holes; removing portions of the second dielectric layers located at the array region through the second trench to form second gaps; removing the sacrificial material from the first trench and the first gaps; filling the first gaps and the second gaps with a conductive material; and forming the first GLS structure segment in the first trench and forming the second GLS structure segment in the second trench.

In some implementations, after forming the first trench, the method further includes: enlarging the first trench by removing portions of the first dielectric layer and the second dielectric layer exposed by the first trench; and oxidizing the semiconductor layer and the substrate exposed by the enlarged first trench.

In some implementations, after forming the second trench, the method further includes: enlarging the second trench by removing potions of the first dielectric layer and the second dielectric layer exposed by the second trench; removing portions of the semiconductor layer and the sacrificial material exposed by the enlarged second trench; and oxidizing a side surface of the sacrificial material in the first trench to form an intermedia sub-layer composed of a first material, wherein the side surface of the sacrificial material in the first trench is exposed by the enlarged second trench.

In some implementations, filling the first trench and the first gaps with the sacrificial material includes: filling the first trench and the first gaps with a sacrificial semiconductor material.

In some implementations, forming the intermedia sub-layer includes: forming the intermedia sub-layer having a curved wall structure, where the curved wall structure is convex toward the second GLS structure segment.

In some implementations, the method further includes depositing a second material on both sides of the intermedia sub-layer.

In some implementations, forming the first GLS structure segment in the first trench and forming the second GLS structure segment in the second trench include: depositing a first spacer sub-layer on an inner wall of the first trench; depositing a second spacer sub-layer on an inner wall of the second trench; and filling the first trench and the second trench with a filling material.

In some implementations, filling the first trench and the second trench with the filling material includes: filling the first trench and the second trench with a conductive material.

In some implementations, the method further includes forming dummy channel structures in other first through holes and forming channel structures in other second through holes.

Another aspect of the present disclosure provides a memory device, including: a memory array; and a peripheral circuit disposed on at least one side of the memory array. the memory array includes: a stack structure comprising an array region and a contact region located on a side of the array region in a first lateral direction; and a gate line slit (GLS) structure extending vertically through the stack structure and laterally along the first lateral direction. The GLS structure includes: a dielectric structure extending vertically through the stack structure and located at a boundary between the array region and the contact region; a first GLS structure segment laterally extending from the dielectric structure to the contact region along the first lateral direction; and a second GLS structure segment laterally extending from the dielectric structure to the array region along the first lateral direction, where the dielectric structure separates the first GLS structure segment and the second GLS structure segment, a first dimension of the dielectric structure in the first lateral direction is less than a second dimension of the dielectric structure in a second lateral direction perpendicular to the first lateral direction.

In some implementations, the peripheral circuit is electrically connected to the memory array through conductive interconnects formed in the contact region.

In some implementations, the peripheral circuit is disposed on both sides of the memory array, symmetrically positioned relative to the array region, and connected via lateral interconnects that extend along the first lateral direction.

Other aspects of the present disclosure can be understood by those skilled in the art in light of the description, the claims, and the drawings of the present disclosure.

### BRIEF DESCRIPTION OF DRAWINGS

The accompanying drawings, which are incorporated herein and form a part of the specification, illustrate implementations of the present disclosure and, together with the description, explain the principles of the present disclosure, and enable a person skilled in the pertinent art to make and use the present disclosure.

FIG. 1 illustrates a block diagram of a system having a memory device, according to some aspects of the present disclosure.

FIG. 2A illustrates a diagram of a memory card having a memory device, in accordance with some implementations.

FIG. 2B illustrates a diagram of a solid-state drive (SSD) having a memory in accordance with some implementations.

FIG. 3 illustrates a top-down view of a 3D memory device, according to some implementations of the present disclosure.

FIG. 4 illustrates a perspective view of a portion of a 3D memory array structure, according to some implementations of the present disclosure.

FIG. 5A illustrates a top-down perspective view of a portion of a 3D memory array structure, according to some implementations of the present disclosure.

FIG. 5B1 illustrates a schematic diagram of a portion of the 3D structure in a cross-sectional side view along the AA′ line shown in FIG. 5A, according to some implementations of the present disclosure.

FIG. 5B2 illustrates a schematic diagram of a portion of the 3D structure in a cross-sectional side view along the BB′ line shown in FIG. 5A, according to some implementations of the present disclosure.

FIG. 5B3 illustrates a schematic diagram of a portion of the 3D structure in a cross-sectional side view along the CC′ line shown in FIG. 5A, according to some implementations of the present disclosure.

FIG. 5C illustrates a top-down perspective view of a portion of a 3D memory array structure, according to some implementations of the present disclosure.

FIG. 5D illustrates a schematic diagram of a portion of the 3D structure in a cross-sectional side view along the CC′ line shown in FIG. 5C, according to some implementations of the present disclosure

FIG. 6 illustrates a flow diagram of a method for forming a 3D memory device in accordance with some implementations of the present disclosure.

FIG. 7A illustrates a schematic diagram of a portion of a 3D memory device at a certain fabricating stage of the method shown in FIG. 6 in a top-down perspective view, according to some implementations of the present disclosure.

FIG. 7B1 illustrates a schematic diagram of a portion of the 3D structure in a cross-sectional side view along the AA′ line shown in FIG. 7A, according to some implementations of the present disclosure.

FIG. 7B2 illustrates a schematic diagram of a portion of the 3D structure in a cross-sectional side view along the BB′ line shown in FIG. 7A, according to some implementations of the present disclosure.

FIG. 7B3 illustrates a schematic diagram of a portion of the 3D structure in a cross-sectional side view along the CC′ line shown in FIG. 7A, according to some implementations of the present disclosure.

FIG. 7C illustrates a schematic diagram of a portion of a 3D memory device at a certain fabricating stage of the method shown in FIG. 6 in a top-down perspective view, according to some implementations of the present disclosure.

FIG. 7D1 illustrates a schematic diagram of a portion of the 3D structure in a cross-sectional side view along the AA′ line shown in FIG. 7A, according to some implementations of the present disclosure.

FIG. 7D2 illustrates a schematic diagram of a portion of the 3D structure in a cross-sectional side view along the BB′ line shown in FIG. 7A, according to some implementations of the present disclosure.

FIG. 7D3 illustrates a schematic diagram of a portion of the 3D structure in a cross-sectional side view along the CC′ line shown in FIG. 7A, according to some implementations of the present disclosure.

FIG. 8A illustrates a schematic diagram of a portion of a 3D memory device at a certain fabricating stage of the method shown in FIG. 6 in a top-down perspective view, according to some implementations of the present disclosure.

FIG. 8B1 illustrates a schematic diagram of a portion of the 3D structure in a cross-sectional side view along the AA′ line shown in FIG. 8A, according to some implementations of the present disclosure.

FIG. 8B2 illustrates a schematic diagram of a portion of the 3D structure in a cross-sectional side view along the BB′ line shown in FIG. 8A, according to some implementations of the present disclosure.

FIG. 8B3 illustrates a schematic diagram of a portion of the 3D structure in a cross-sectional side view along the CC′ line shown in FIG. 8A, according to some implementations of the present disclosure.

FIG. 9A illustrates a schematic diagram of a portion of a 3D memory device at a certain fabricating stage of the method shown in FIG. 6 in a top-down perspective view, according to some implementations of the present disclosure.

FIG. 9B1 illustrates a schematic diagram of a portion of the 3D structure in a cross-sectional side view along the AA′ line shown in FIG. 9A, according to some implementations of the present disclosure.

FIG. 9B2 illustrates a schematic diagram of a portion of the 3D structure in a cross-sectional side view along the BB′ line shown in FIG. 9A, according to some implementations of the present disclosure.

FIG. 9B3 illustrates a schematic diagram of a portion of the 3D structure in a cross-sectional side view along the CC′ line shown in FIG. 9A, according to some implementations of the present disclosure.

FIG. 10A illustrates a schematic diagram of a portion of a 3D memory device at a certain fabricating stage of the method shown in FIG. 6 in a top-down perspective view, according to some implementations of the present disclosure.

FIG. 10B1 illustrates a schematic diagram of a portion of the 3D structure in a cross-sectional side view along the AA′ line shown in FIG. 10A, according to some implementations of the present disclosure.

FIG. 10B2 illustrates a schematic diagram of a portion of the 3D structure in a cross-sectional side view along the BB′ line shown in FIG. 10A, according to some implementations of the present disclosure.

FIG. 10B3 illustrates a schematic diagram of a portion of the 3D structure in a cross-sectional side view along the CC′ line shown in FIG. 10A, according to some implementations of the present disclosure.

FIG. 11A illustrates a schematic diagram of a portion of a 3D memory device at a certain fabricating stage of the method shown in FIG. 6 in a top-down perspective view, according to some implementations of the present disclosure.

FIG. 11B1 illustrates a schematic diagram of a portion of the 3D structure in a cross-sectional side view along the AA′ line shown in FIG. 11A, according to some implementations of the present disclosure.

FIG. 11B2 illustrates a schematic diagram of a portion of the 3D structure in a cross-sectional side view along the BB′ line shown in FIG. 11A, according to some implementations of the present disclosure.

FIG. 11B3 illustrates a schematic diagram of a portion of the 3D structure in a cross-sectional side view along the CC′ line shown in FIG. 11A, according to some implementations of the present disclosure.

FIG. 12A illustrates a schematic diagram of a portion of a 3D memory device at a certain fabricating stage of the method shown in FIG. 6 in a top-down perspective view, according to some implementations of the present disclosure.

FIG. 12B1 illustrates a schematic diagram of a portion of the 3D structure in a cross-sectional side view along the AA′ line shown in FIG. 12A, according to some implementations of the present disclosure.

FIG. 12B2 illustrates a schematic diagram of a portion of the 3D structure in a cross-sectional side view along the BB′ line shown in FIG. 12A, according to some implementations of the present disclosure.

FIG. 12B3 illustrates a schematic diagram of a portion of the 3D structure in a cross-sectional side view along the CC′ line shown in FIG. 12A, according to some implementations of the present disclosure.

FIG. 13A1-13A3 illustrate schematic diagrams of the 3D structure in cross-sectional side views according to some implementations of the present disclosure.

FIG. 14A illustrates a schematic diagram of a portion of a 3D memory device at a certain fabricating stage of the method shown in FIG. 6 in a top-down perspective view, according to some implementations of the present disclosure.

FIG. 14B1 illustrates a schematic diagram of a portion of the 3D structure in a cross-sectional side view along the AA′ line shown in FIG. 14A, according to some implementations of the present disclosure.

FIG. 14B2 illustrates a schematic diagram of a portion of the 3D structure in a cross-sectional side view along the BB′ line shown in FIG. 14A, according to some implementations of the present disclosure.

FIG. 14B3 illustrates a schematic diagram of a portion of the 3D structure in a cross-sectional side view along the CC′ line shown in FIG. 14A, according to some implementations of the present disclosure.

FIG. 15A illustrates a schematic diagram of a portion of a 3D memory device at a certain fabricating stage of the method shown in FIG. 6 in a top-down perspective view, according to some implementations of the present disclosure.

FIG. 15B1 illustrates a schematic diagram of a portion of the 3D structure in a cross-sectional side view along the AA′ line shown in FIG. 15A, according to some implementations of the present disclosure.

FIG. 15B2 illustrates a schematic diagram of a portion of the 3D structure in a cross-sectional side view along the BB′ line shown in FIG. 15A, according to some implementations of the present disclosure.

FIG. 15B3 illustrates a schematic diagram of a portion of the 3D structure in a cross-sectional side view along the CC′ line shown in FIG. 15A, according to some implementations of the present disclosure.

FIG. 16A1-16A3 illustrate schematic diagrams of the 3D structure in cross-sectional side views according to some implementations of the present disclosure.

FIG. 17A illustrates a schematic diagram of a portion of a 3D memory device at a certain fabricating stage of the method shown in FIG. 6 in a top-down perspective view, according to some implementations of the present disclosure.

FIG. 17B1 illustrates a schematic diagram of a portion of the 3D structure in a cross-sectional side view along the AA′ line shown in FIG. 17A, according to some implementations of the present disclosure.

FIG. 17B2 illustrates a schematic diagram of a portion of the 3D structure in a cross-sectional side view along the BB′ line shown in FIG. 17A, according to some implementations of the present disclosure.

FIG. 17B3 illustrates a schematic diagram of a portion of the 3D structure in a cross-sectional side view along the CC′ line shown in FIG. 17A, according to some implementations of the present disclosure.

FIG. 18A illustrates a schematic diagram of a portion of a 3D memory device at a certain fabricating stage of the method shown in FIG. 6 in a top-down perspective view, according to some implementations of the present disclosure.

FIG. 18B1 illustrates a schematic diagram of a portion of the 3D structure in a cross-sectional side view along the AA′ line shown in FIG. 18A, according to some implementations of the present disclosure.

FIG. 18B2 illustrates a schematic diagram of a portion of the 3D structure in a cross-sectional side view along the BB′ line shown in FIG. 18A, according to some implementations of the present disclosure.

FIG. 18B3 illustrates a schematic diagram of a portion of the 3D structure in a cross-sectional side view along the CC′ line shown in FIG. 18A, according to some implementations of the present disclosure.

FIG. 19A illustrates a schematic diagram of a portion of a 3D memory device at a certain fabricating stage of the method shown in FIG. 6 in a top-down perspective view, according to some implementations of the present disclosure.

FIG. 19B1 illustrates a schematic diagram of a portion of the 3D structure in a cross-sectional side view along the AA′ line shown in FIG. 19A, according to some implementations of the present disclosure.

FIG. 19B2 illustrates a schematic diagram of a portion of the 3D structure in a cross-sectional side view along the BB′ line shown in FIG. 19A, according to some implementations of the present disclosure.

FIG. 19B3 illustrates a schematic diagram of a portion of the 3D structure in a cross-sectional side view along the CC′ line shown in FIG. 19A, according to some implementations of the present disclosure.

FIG. 20A illustrates a schematic diagram of a portion of a 3D memory device at a certain fabricating stage of the method shown in FIG. 6 in a top-down perspective view, according to some implementations of the present disclosure.

FIG. 20B1 illustrates a schematic diagram of a portion of the 3D structure in a cross-sectional side view along the AA′ line shown in FIG. 20A, according to some implementations of the present disclosure.

FIG. 20B2 illustrates a schematic diagram of a portion of the 3D structure in a cross-sectional side view along the BB′ line shown in FIG. 20A, according to some implementations of the present disclosure.

FIG. 20B3 illustrates a schematic diagram of a portion of the 3D structure in a cross-sectional side view along the CC′ line shown in FIG. 20A, according to some implementations of the present disclosure.

FIG. 21A illustrates a schematic diagram of a portion of a 3D memory device at a certain fabricating stage of the method shown in FIG. 6 in a top-down perspective view, according to some implementations of the present disclosure.

FIG. 21B1 illustrates a schematic diagram of a portion of the 3D structure in a cross-sectional side view along the AA′ line shown in FIG. 21A, according to some implementations of the present disclosure.

FIG. 21B2 illustrates a schematic diagram of a portion of the 3D structure in a cross-sectional side view along the BB′ line shown in FIG. 21A, according to some implementations of the present disclosure.

FIG. 21B3 illustrates a schematic diagram of a portion of the 3D structure in a cross-sectional side view along the CC′ line shown in FIG. 21A, according to some implementations of the present disclosure.

FIG. 22A illustrates a schematic diagram of a portion of a 3D memory in a top-down perspective view, according to some implementations of the present disclosure.

FIG. 22B illustrates a schematic diagram of a portion of the 3D structure in a cross-sectional side view along the AA′ line shown in FIG. 22A, according to some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of an Homogeneous or inhomogeneous continuous structure that has a thickness less than the thickness of the continuous structure. For example, a layer can be located between any pair of lateral planes between, or at, a top surface and a bottom surface of the continuous structure. A layer can extend laterally, vertically, and/or along a tapered surface. A substrate can be a layer, can include one or more layers therein, and/or can have one or more layer thereupon, thereabove, and/or therebelow. A layer can include multiple layers. For example, an interconnection layer can include one or more conductor and contact layers (in which contacts, interconnect lines, and/or vias are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “3D memory device” refers to a semiconductor device with vertically-oriented strings of memory cell transistors (i.e., region herein as “memory strings,” such as NAND strings) on a laterally-oriented substrate so that the memory strings extend in the vertical direction with respect to the substrate. As used herein, the term “vertical/vertically” means nominally perpendicular to a lateral surface of a substrate.

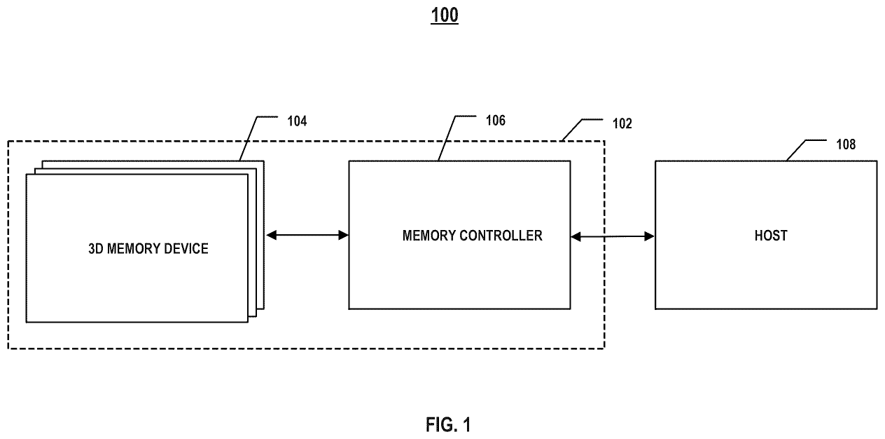

FIG. 1 illustrates a block diagram of a system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive the data to or from memory devices 104.

Memory device 104 can be any memory devices disclosed herein, such as a NAND Flash memory device. Consistent with the scope of the present disclosure, memory controller 106 may control the multi-pass programming on memory device 104 such that an NGS operation is enabled on all memory cells, even those passed the respective verify operations, in a non-last programming pass of the multi-pass programming. The peripheral circuits, such as the word line drivers, may apply a low voltage, e.g., ground (GND) voltage, on the DSGs of each memory string coupled to the selected word line, and may apply a low or negative voltage on the selected word line to enable an NGS operation on all memory cells coupled to the selected word line during a non-last programming pass.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, programming memory device 104. Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

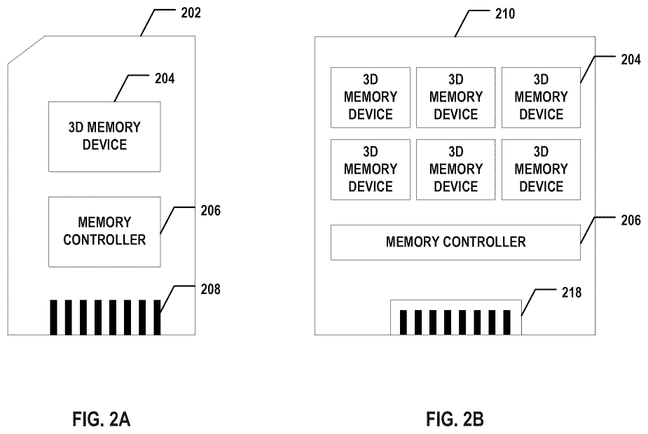

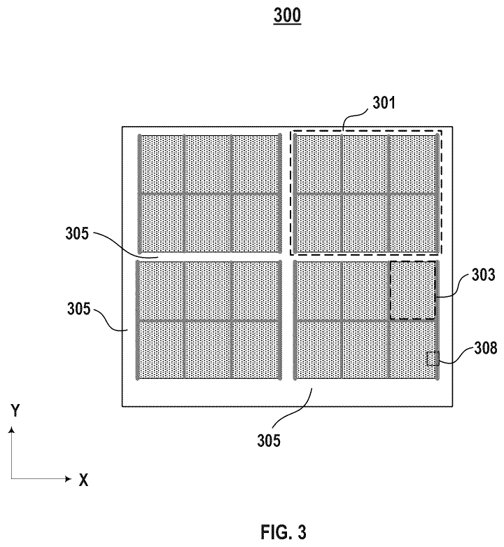

Memory controller 106 and one or more memory devices 104 can be integrated into various types of storage devices, for example, be included in the same package, such as a universal Flash storage (UFS) package or an eMMC package. That is, memory system 102 can be implemented and packaged into different types of end electronic products. In one example as shown in FIG. 2A, memory controller 206 and a single memory device 204 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 208 coupling memory card 202 with a host (e.g., host 108 in FIG. 1). In another example as shown in FIG. 2B, memory controller 106 and multiple memory devices 104 may be integrated into an SSD 210. SSD 210 can further include an SSD connector 218 coupling SSD 210 with a host (e.g., host 108 in FIG. 1). In some implementations, the storage capacity and/or the operation speed of SSD 210 is greater than those of memory card 202.

FIG. 3 illustrates a top-down view of a 3D memory device 300, according to some implementations of the present disclosure. 3D memory device 300 can be a memory chip (package), a memory chip or any portion of a memory chip, and can include one or more memory planes 301, each of which can include a plurality of memory blocks 303. Identical and concurrent operations can take place at each memory plane 301. Memory block 303, which can be megabytes (MB) in size, can be the smallest size to carry out erase operations. Shown in FIGS. 3, 3D memory device 300 includes four memory planes 301 and each memory plane 301 includes six memory blocks 303. Each memory block 303 can include a plurality of memory cells, where each memory cell can be addressed through interconnections such as bit lines and word lines. The bit lines and word lines can be laid out perpendicularly (e.g., in rows and columns, respectively), forming an array of metal lines. In FIG. 3, the direction of word lines is referred to herein as a first lateral direction and labeled as X-direction, and the direction of bit lines is referred to herein as a second lateral direction and labeled as Y-direction. In this disclosure, memory block 303 is also referred to as a “memory array” or “array.” The memory array is the core area in a memory device, performing storage functions.

3D memory device 300 can include a periphery region 305, an area surrounding memory planes 301. Periphery region 305 can contain many digital, analog, and/or mixed-signal circuits to support functions of the memory array, for example, page buffers, row and column decoders and sense amplifiers. Peripheral circuits use active and/or passive semiconductor devices, such as transistors, diodes, capacitors, resistors, etc., as would be apparent to a person of ordinary skill in the art. It is noted that, the arrangement of memory planes 301 in 3D memory device 300 and the arrangement of memory blocks 303 in each memory plane 301 illustrated in FIG. 3 are only provided as an example, which does not limit the scope of the present disclosure.

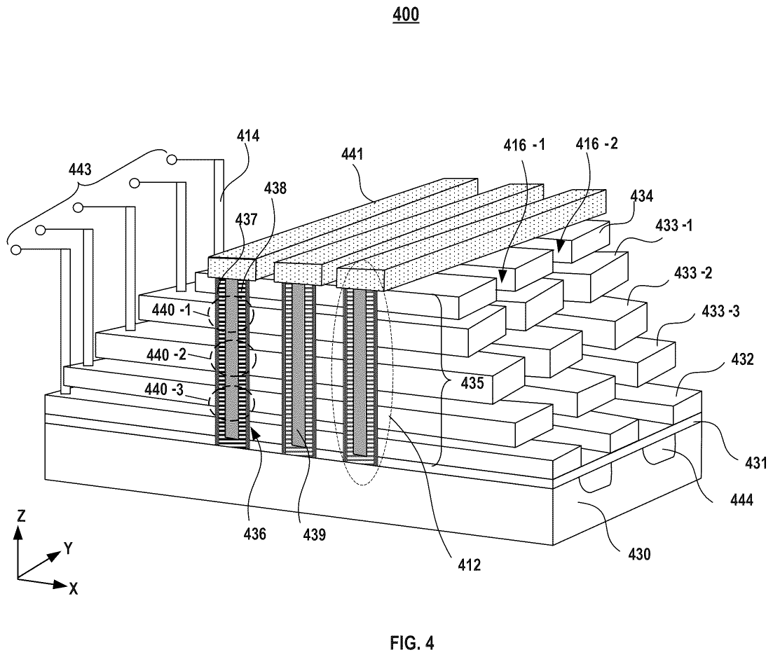

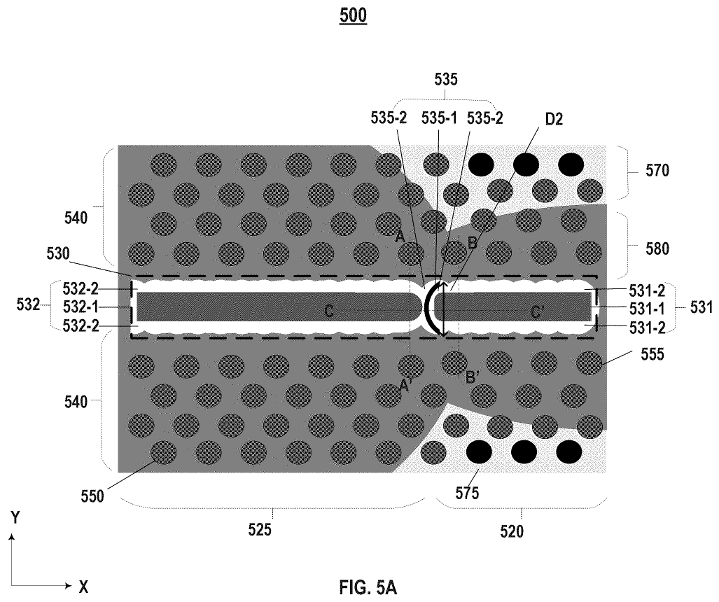

FIG. 4 illustrates a perspective view of a portion of a 3D memory array structure 400, according to some implementations of the present disclosure. Memory array structure 400 includes a substrate 430, an insulating film 431 over the substrate 430, one or more tiers of bottom select gates (BSGs) 432 over the insulating film 431, and a plurality of tiers of control gates 433, also referred to as “word lines (WLs),” stacking on top of the BSGs 432 to form a stack structure 435 of alternating conductive and dielectric layers. The dielectric layers adjacent to the tiers of control gates are not shown in FIG. 4 for clarity.

The control gates 433 of each tier are separated by slit structures 416-1 and 416-2 through stack structure 435. Memory array structure 400 can include one or more tiers of top select gates (TSGs) 434 over the stack of control gates 433. The stack of TSG 434, control gates 433 and BSG 432 are also referred to as “gate structures.” Memory array structure 400 further includes memory strings 412 and doped source line regions 444 in portions of substrate 430 between adjacent BSGs 432. Each memory string 412 includes a channel hole 436 extending through insulating film 431 and stack structure 435 of alternating conductive and dielectric layers. Memory strings 412 can also include a memory film 437 (also referred as “functional layer”) on a sidewall of the channel hole 436, a channel layer 438 over the memory film 437, and a core filling film 439 surrounded by the channel layer 438. A memory cell 440 can be formed at the intersection of control gate 433 and memory string 412. Memory array structure 400 further includes a plurality of bit lines (BLs) 441 connected with memory strings 412 over TSGs 434. Memory array structure 400 can include a plurality of metal interconnect lines 443 connected with the gate structures through a plurality of gate line contact structures 414.

In FIG. 4, for illustrative purposes, three tiers of control gates 433-1, 433-2, and 433-3 are shown together with one tier of TSG 434 and one tier of BSG 432. In this example, each memory string 412 can include three memory cells 440-1, 440-2 and 440-3, corresponding to the control gates 433-1, 433-2 and 433-3, respectively. In some implementations, the number of control gates and the number of memory cells can be more than three to increase storage capacity. Memory array structure 400 can also include other structures, for example, TSG cuts, common source contacts, and dummy channel structures. These structures are not shown in FIG. 4 for simplicity.

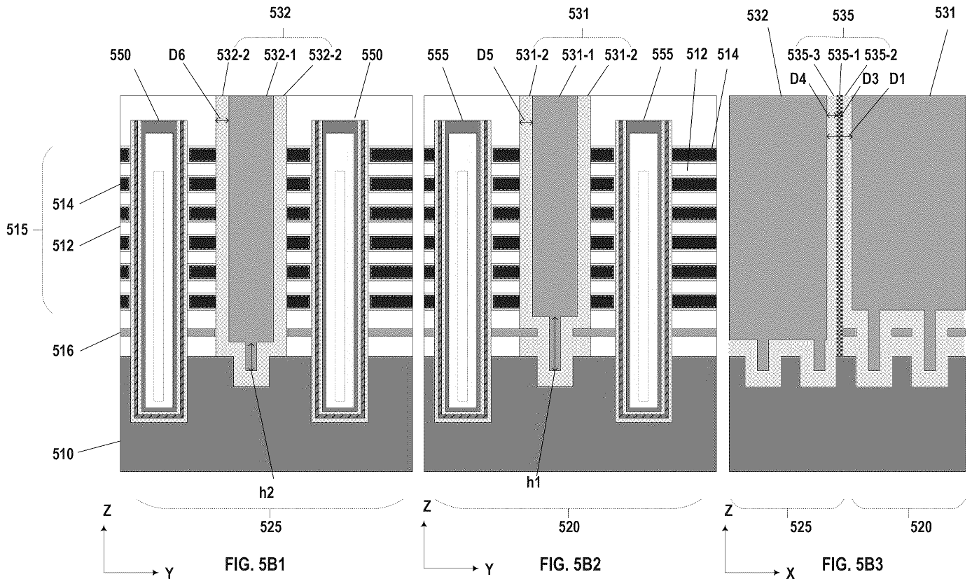

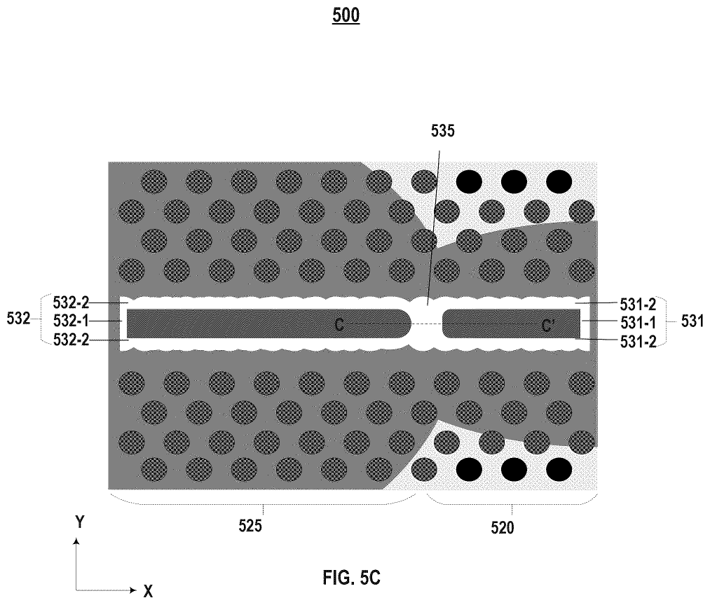

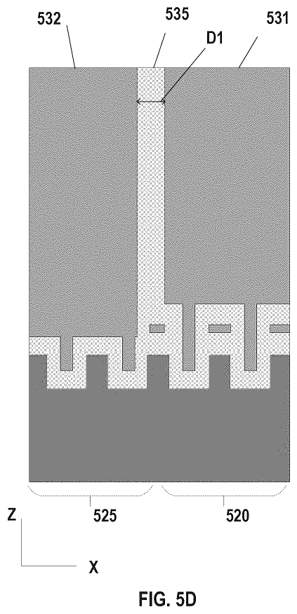

Referring to FIG. 5A, schematic diagrams of a portion 500 of 3D memory device, such as region 308 of FIG. 3, are shown in an enlarged top-down view and cross-sectional side view, respectively, according to some implementations of the present disclosure. FIG. 5B1 illustrates a schematic diagram of a portion of the 3D structure in a cross-sectional side view along the AA′ line shown in FIG. 5A, according to some implementations of the present disclosure. FIG. 5B2 illustrates a schematic diagram of a portion of the 3D structure in a cross-sectional side view along the BB′ line shown in FIG. 5A, according to some implementations of the present disclosure. FIG. 5B3 illustrates a schematic diagram of a portion of the 3D structure in a cross-sectional side view along the CC′ line shown in FIG. 5A, according to some implementations of the present disclosure.

The portion 500 of 3D memory device may be bonded with another semiconductor structure including a peripheral circuit electrically connected to the memory array through conductive interconnects formed in the contact region. In some implementations, the peripheral circuit is disposed on both sides of the memory array, symmetrically positioned relative to the array region, and connected via lateral interconnects that extend along the first lateral direction.

As shown in FIGS. 5A and 5B1-5B3, portion 500 of 3D memory device can include a stack structure 515, and the stack structure 515 can have an array region 525 including a plurality of channel structures 550, and a contact region 520 including a plurality of dummy channel structure 555 and a plurality of gate line contact structures 575. The contact region 520 is located on a side of the array region 525 in a first lateral direction (i.e., X-direction). A slit can laterally extend in parallel along the first direction and vertically extend through the stack structure 515. A gate line slit (GLS) structure 530 can be formed in the slit to divide the memory array into two memory fingers 540. The GLS structure 530 extends vertically through the stack structure 515 and laterally along the first lateral direction. Each memory finger 540 can include multiple (e.g., four) rows of channel structures 550 arranged in a staggered manner. The channel structures 550 can vertically extend through a conductive/dielectric stack structure.

In some implementations as shown in FIG. 5A, the GLS structure 530 (the structure encircled by a dash rectangle as shown in FIG. 5A) can include a dielectric structure 535 extending vertically through the stack structure 515 and located at a boundary between the array region 525 and the contact region 520, a first GLS structure segment 531 laterally extending from the dielectric structure 535 to the contact region 520 along the first lateral direction, and a second GLS structure segment 532 laterally extending from the dielectric structure to the array region 525 along the first lateral direction. The dielectric structure 535 separates the first GLS structure segment 531 and the second GLS structure segment 532, a first dimension D1 (as shown in FIG. 5B3) of the dielectric structure 535 in the first lateral direction is less than a second dimension D2 (as shown in FIG. 5A) of the dielectric structure 535 in a second lateral direction (i.e., Y-direction) perpendicular to the first lateral direction. The first dimension D1 can be in a range from about 30 nm to about 200 nm, while the second dimension D2 can be in a range from about 500 nm to about 1000 nm.

As shown in FIGS. 5A and 5B1-5B3, in some implementations, each of the first and second GLS structure segments 531 and 532 includes a wall structure laterally extending in the first lateral direction (X-direction) and insulated from the conductive layers 514 of the stack structure 515. In some implementations, the first GLS structure segment 531 is located in the contact region 520, the second GLS structure segment 532 is located in the array region 525, and the dielectric structure 535 can be located at a boundary between the array region 525 and the contact region 520. The first GLS structure segment 531 includes a first filling wall 531-1 sandwiched between first spacer layers 531-2 along the second lateral direction. The second GLS structure segment 532 includes a second filling wall 532-1 sandwiched between second spacer layers 532-2 along the second lateral direction. As shown in FIG. 5A, sidewalls of the first GLS structure segment 531 and the second GLS structure segment 532 in second first lateral direction may include curved surfaces.

As shown in FIG. 5B1-5B3, in some implementations, each of the first filling wall 531-1 and the second filling wall 532-1 includes an upper portion and a lower portion, and a dimension of the upper portion is greater than a dimension of the lower portion along the second lateral direction. The lower portion of the first filling wall 531-1 may include protruding portions each having a lateral surface and a bottom surface surrounded by the first spacer layers 531-2 from all lateral directions and a bottom direction. The lower portion of the second filling wall 532-1 may also include protruding portions each having a lateral surface and a bottom surface surrounded by the second spacer layers 532-2 from all lateral directions and a bottom direction. As shown in FIG. 5B1-5B2, in some implementations, a first height h1 (as shown in FIG. 5B2) of first protruding portions of the first filling wall 531-1 in a vertical direction is greater than a second height h2 (as shown in FIG. 5B1) of second protruding portions of the second filling wall 532-1 in the vertical direction. In some implementations, the first protruding portions of the first filling wall 531-1 and second protruding portions of the second filling wall 532-1 vertically extend into an upper portion of a substrate 510.

In some implementations, as shown in FIG. 5B1-5B3, the portion 500 of 3D memory device may include a semiconductor layer 516 located between the stack structure 515 and the substrate 510. A top surface of the semiconductor layer 516 is lower than a bottom surface of the upper portion of the first filling wall 531-1, and a bottom surface of the semiconductor layer 516 is higher than a bottom surface of the upper portion of the second filling wall 532-1. In some implementations, the semiconductor layer 516 includes multiple ends extended into the second spacer layers 532-2 and multiple separated portions between the first protruding portions of the first filling wall 531-1. Each separated portion has a lateral surface, a bottom surface, and a top surface surrounded by the first spacer layers 531-2 from all lateral directions, the bottom direction and a top direction.

In some implementations, as shown in FIG. 5B3, the dielectric structure 535 is a composite structure, which includes an intermedia sub-layer 535-1, a first spacer sub-layer 535-2 between the intermedia sub-layer 535-1 and the first GLS structure segment 531, and a second spacer sub-layer 535-3 between the intermedia sub-layer 535-1 and the second GLS structure segment 532. In some implementations, the intermedia sub-layer 535-1 may include a first material, the first spacer sub-layer 535-2 may include a second material different from the first material but same as the first spacer layers 531-2 of the first GLS structure segment 531, and the second spacer sub-layer 535-3 may include a third material different from the first material but same as the second spacer layers 532-2 of the second GLS structure segment 532. In some implementations, the first material can be an oxide material, such as silicon dioxide (SiO₂). The second material can be another oxide material, such as aluminum oxide (Al₂O₃), or hafnium oxide (HfO₂), or it can be a nitride material, such as silicon nitride (Si₃N₄) or aluminum nitride (AlN). The third material may include the oxide or nitride material same as the second material, chosen for compatibility with the specific properties required for the dielectric structure. In some implementations, the second material and the third material are deposited on both sides of the intermedia sub-layer 535-1 in the first lateral direction. In some implementations, a cross section of the intermedia sub-layer 535-1 along the lateral plane (i.e., X-Y plane) can have a curved wall structure, and the curved wall structure is convex toward the second GLS structure segment 531.

In some implementations, the dielectric structure 535 is a single oxide layer as shown in FIG. 5C and FIG. 5D. The dielectric structure has the first dimension in the first lateral direction greater than a summation of a first thickness D5 (as shown in FIG. 5B2) of the first spacer layer 531-2 in the second lateral direction and a second thickness D6 (as shown in FIG. 5B1) of the second spacer layer 535-2 in the second lateral direction.

As shown in FIG. 5A, each memory finger 540 in the contact region 520 can include conductive/dielectric stack region 580 adjacent to the first GLS structure segment 531, and a dielectric stack region 570 located on a side of the conductive/dielectric stack region 580 away from the first GLS structure segment 531. In some implementations, each conductive/dielectric stack regions 580 includes a conductive/dielectric stack including conductive layers 514 and first dielectric layers 512 alternatively stacked in the vertical direction (Z-direction).

As shown in FIGS. 5A and 5B1-5B3, a plurality of dummy channel structures 555 can be located in the conductive/dielectric stack regions 580 of the contact region 520, and a plurality of gate line contact structure 575 can be located in the dielectric stack region 570 of the contact region 520. In some implementations, the channel structures 550 and the dummy channel structures 555 can include similar structures. For example, each of the channel structures 550 and the dummy channel structures 555 can include a functional layer, a channel layer, and a filling structure, which will be described in detail below.

As shown in FIG. 5A, a plurality of gate line contact structures 575 can extend vertically in the dielectric stack region 570 of the contact region 520. In some implementations, each gate line contact structure 575 includes a conductive via structure vertically extends through an upper portion of the dielectric stack structure, and a conductive landing layer in contact with the lower end of the conductive via. The conductive landing layer can laterally connect to a corresponding conductive layer of the conductive/dielectric stack in the conductive/dielectric stack region 580.

In some implementations, the stack structure 515 in the array region 525 includes conductive layers 514 and first dielectric layers 512 alternatively stacked in the vertical direction (i.e., Z-direction). The stack structure 515 in the contact region 520 includes a first stack portion adjacent to the first GLS structure segment 531 and a second stack portion separated from the first GLS structure segment 531. The first stack portion includes the conductive layers 514 and the first dielectric layers 512 alternatively stacked in the vertical direction. The second stack portion includes the first dielectric layers 512 and second dielectric layers (not shown) alternatively stacked in the vertical direction.

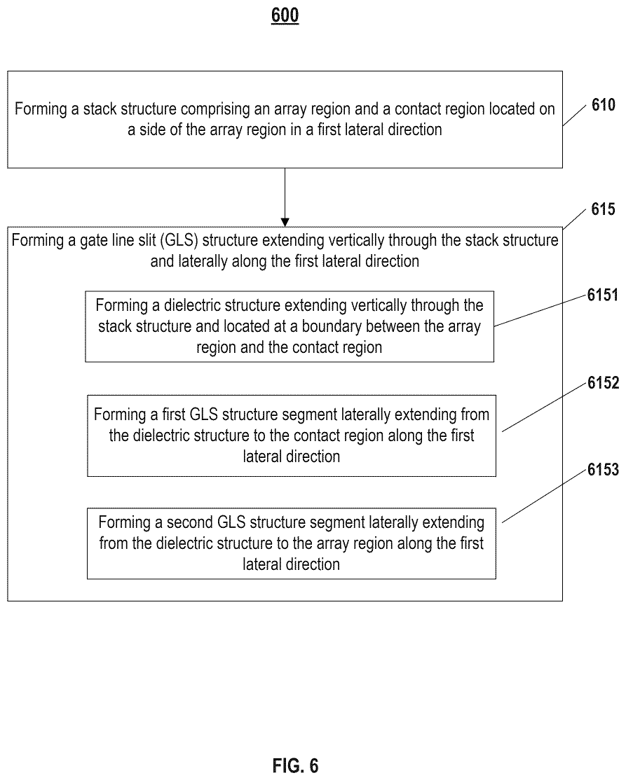

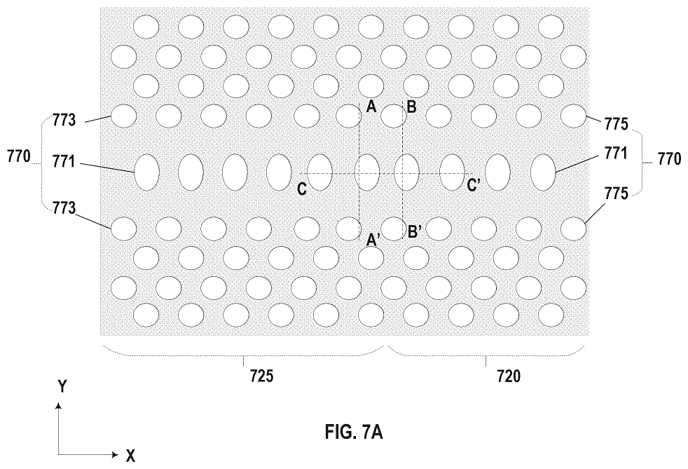

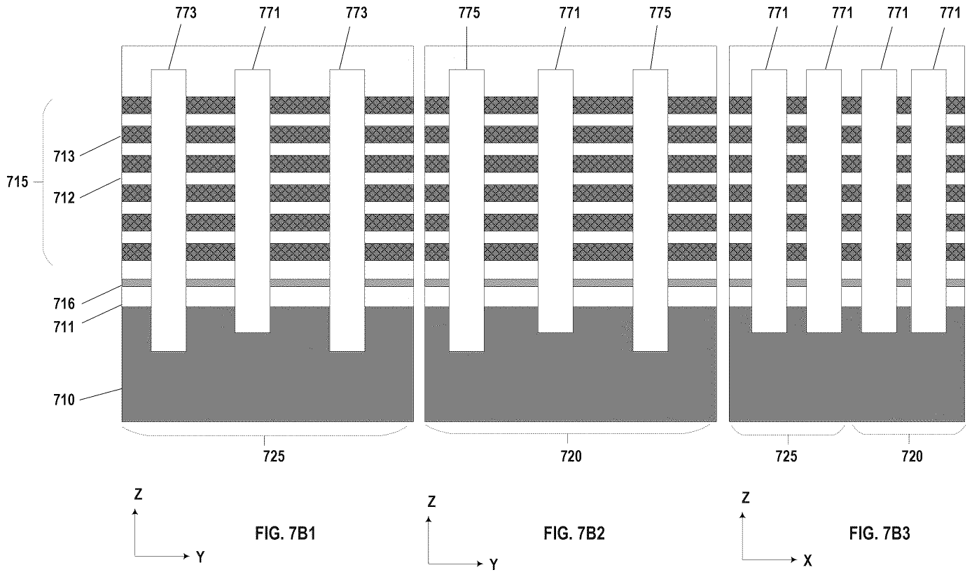

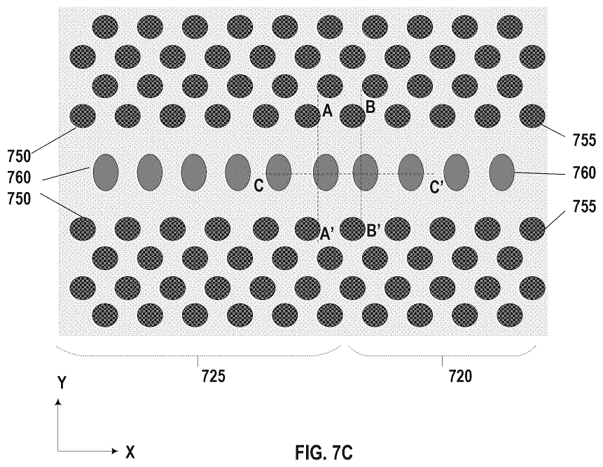

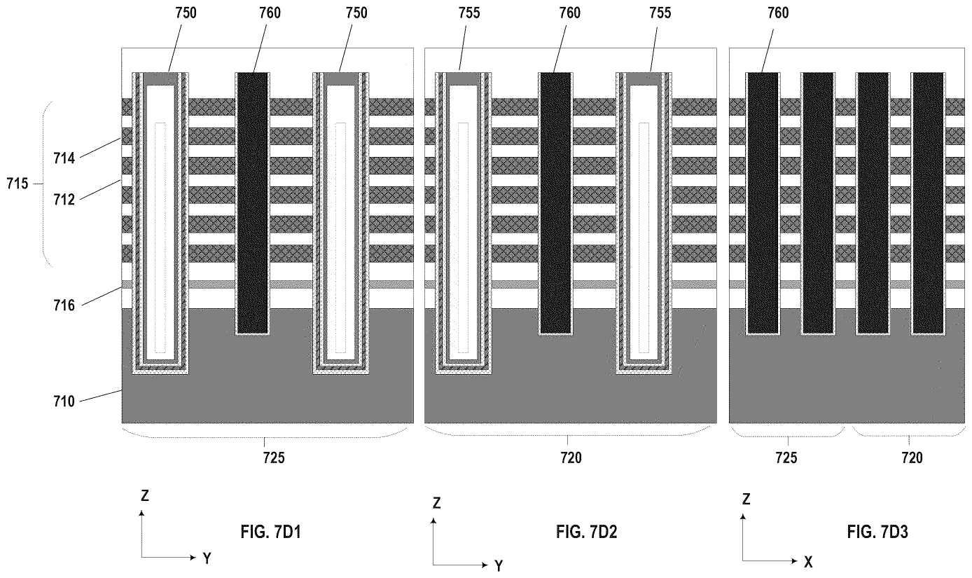

Referring to FIG. 6, a flow diagram of a method 600 for forming a 3D memory device is shown in accordance with some implementations of the present disclosure. FIGS. 7A, 7B1-7B3, 7C, 7D 1-7D3, 8A, 8B 1-8B3, 9A, 9B 1-9B3, 10A, 10B1-10B3, 11A, 11B1-11B3, 12A, 12B1-B3, 13A1-13A3, 14A, 14B1-14B3, 15A, 15B1-15B3, 16A1-16A3, 17A, 17B1-17B3, 18A, 18B1-18B3, 19A, 19B1-19B3, 20A, 20B 1-20B3, 21A, 2 1B1-21B3, 22A and 22B illustrate schematics of portions of a 3D memory device at certain fabricating stages of the method 600 shown in FIG. 6 in various views, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, the method can start at operation 610, in which a stack structure can be formed to include an array region and a contact region located on a side of the array region in a first lateral direction. FIG. 7A illustrates a schematic diagram of the 3D structure after forming the stack structure at operation 610 in a top-down perspective view, according to some implementations of the present disclosure. FIG. 7B1 illustrates a schematic diagram of a portion of the 3D structure in a cross-sectional side view along the AA′ line shown in FIG. 7A, according to some implementations of the present disclosure. FIG. 7B2 illustrates a schematic diagram of a portion of the 3D structure in a cross-sectional side view along the BB′ line shown in FIG. 7A, according to some implementations of the present disclosure. FIG. 7B3 illustrates a schematic diagram of a portion of the 3D structure in a cross-sectional side view along the CC′ line shown in FIG. 7A, according to some implementations of the present disclosure.

As shown in FIG. 7B1-7B3, in some implementations, an insulating layer 711 can be formed on a substrate 710. The substrate 710 can be any suitable semiconductor substrate having any suitable structure, such as a monocrystalline single-layer substrate, a polycrystalline silicon (polysilicon) single-layer substrate, a polysilicon and metal multi-layer substrate, etc. The insulating layer 711 can include any suitable dielectric material such as silicon dioxide (SiO₂), silicon nitride (Si₃N₄), or aluminum oxide (Al₂O₃), with any appropriate structure. A semiconductor layer 716 may be formed on the insulating layer 711. The semiconductor layer 716 can include semiconductor materials such as monocrystalline silicon, polysilicon, or germanium. A stack structure 715 can be formed on the semiconductor layer 716.

In some implementations, the stack structure 715 can include a plurality of silicon oxide/nitride layer pairs as shown in FIG. 7B1-FIG. 7B3. For example, each dielectric layer pair includes a layer of silicon oxide and a layer of silicon nitride. The stack structure 715 can be formed by one or more thin film deposition processes including, but not limited to, Chemical Vapor Deposition (CVD), Physical Vapor Deposition (PVD), Atomic Layer Deposition (ALD), or any combination thereof. The plurality of oxide/nitride layer pairs are also referred to herein as an “alternating oxide/nitride stack.” That is, in the stack structure 715, multiple oxide layers 712 and multiple nitride layers 713 alternate in a vertical direction (i.e., Z-direction). In other words, except a top and a bottom layer of a given alternating oxide/nitride stack, each of the other oxide layers 712 can be sandwiched by two adjacent nitride layers 713, and each of the nitride layers 713 can be sandwiched by two adjacent oxide layers 712.

Oxide layers can each have the same thickness or have different thicknesses. For example, the thickness of each oxide layer can be in a range from 10 nm to 100 nm, preferably about 25 nm. Similarly, nitride layers can each have the same thickness or have different thicknesses. For example, the thickness of each nitride layer can be in a range from 10 nm to 100 nm, preferably about 35 nm.

It is noted that, in the present disclosure, the oxide layers 712 and/or nitride layers 713 can include any suitable oxide materials and/or nitride materials. For example, the oxide materials can include silicides, and the element of nitride materials can include, but not limited to, tungsten (W), cobalt (Co), copper (Cu), aluminum (Al), doped silicon, silicides, or any combination thereof. In some implementations, the oxide layers can be silicon oxide layers, and the nitride layers can be silicon nitride layer.

The stack structure 715 can include any suitable number of layers of the oxide layers 712 and the nitride layers 713. In some implementations, the total number of layers of the oxide layers 712 and the nitride layers 713 in the stack structure 715 is equal to or larger than 64. That is, a number of oxide/nitride layer pairs can be equal to or larger than 32. In some implementations, the alternating oxide/nitride stack includes more oxide layers or more nitride layers with different materials and/or thicknesses than the oxide/nitride layer pair.

As shown in FIGS. 7A and 7B1-7B3, a plurality of through holes 770 can be formed in the contact region 720 and the array region 725 of the stack structure 715 at operation 610. In some implementations, the plurality of through holes are laterally aligned along a first lateral direction (X-direction) and each extending vertically through the stack structure 715. In some implementations, the plurality of through holes 770 include first through holes 771 located in both of the array region 725 and the contact region 720. In some implementations, the plurality of through holes 770 can further include second through holes 773 located in the array region 725. The second through holes 773 can be arranged in a stagged array form in the array region 725. In some implementations, the plurality of through holes 770 can further include third through holes 775 located in the contact region 720. In some implementations, the first through holes 771, the second through holes 773, and the third through holes 775 can be formed simultaneously.

A process of forming the plurality of through holes 770 can include forming a hard mask layer (not shown) on the stack structure 715, and coating a photoresist layer (not shown) on the hard mask layer. A pattering process can be performed to pattern the hard mask layer. Using the hard mask layer as a mask, an etching process can be followed to etch the stack structure 715 to form the plurality of through holes 770. Each plurality of through holes 770 can completely penetrate the stack structure 715 and extend into the substrate 710. The etching process to form the plurality of through holes 770 can be a dry etching, a wet etching, or a combination thereof. After the etching process, the photoresist layer and the hard mask layer can be removed. In some implementations, the plurality of through holes 770 can be formed in a same patterning process by using a single mask.

As shown in FIGS. 7C and 7D1-7D3, a plurality of sacrificial filling structures 760 can be formed in the plurality of first through holes 771, a plurality of channel structures 750 can be formed inside the second through holes 773 in the array region 725, and a plurality of dummy channel structures 755 can be formed inside the third through holes 775 in the contact region 720 of the stack structure 715 at operation 610. FIG. 7C illustrates a schematic diagram of the 3D structure in a top-down perspective view, corresponding to FIG. 7A after forming the plurality of sacrificial filling structures 760, the plurality of channel structures 750, and the plurality of dummy channel structure 755 at certain stage of operation 610. FIG. 7D1 illustrates a schematic diagram of a portion of the 3D structure in a cross-sectional side view along the AA′ line shown in FIG. 7C, according to some implementations of the present disclosure. FIG. 7D2 illustrates a schematic diagram of a portion of the 3D structure in a cross-sectional side view along the BB′ line shown in FIG. 7C, according to some implementations of the present disclosure. FIG. 7D3 illustrates a schematic diagram of a portion of the 3D structure in a cross-sectional side view along the CC′ line shown in FIG. 7C, according to some implementations of the present disclosure.

In some implementations, for the forming of the plurality of sacrificial filling structure 760, a deposition process can be performed to fill the through holes 771 with any suitable sacrificial material (e.g., carbon-based materials). It is noted that, the sacrificial material of the sacrificial filling structures 760 can have a sufficiently high etching selectivity in respect of the materials of the oxide layers 712, the nitride layers 714, the semiconductor layer 716, the insulating layer 711, and the substrate 710, such that a subsequent etching process of the sacrificial filling structures 760 can have minimal impact on of the oxide layers 712, the nitride layers 714, the semiconductor layer 716, the insulating layer 711, and the substrate 710.

As shown in FIGS. 7C and 7D1-7D3, in some implementations, the plurality of channel structures 750 can be formed in the second through holes 773 in the array region 725, and the plurality of dummy channel structure 755 can be formed in the third through holes 775. Each channel structure 750 and dummy channel structure 755 can vertically extend through the stack structure 715 into the substrate 710. In some implementations, the channel structures 750 and the dummy channel structures 755 can include similar structures including, an optional high-K dielectric layer (not shown), a functional layer on the sidewall of the channel hole or covering the high-K dielectric layer, a channel layer covering the functional layer, and a filling structure enclosed by the channel layer. In some implementations, the functional layer can include a barrier layer, a storage layer, and a tunneling layer. In some implementations, the plurality of dummy channel structures 755 can have an oval-shaped cross section in the lateral plane (X-Y plane) with a longitudinal axis in the word line direction (X-direction).

In some implementations, the plurality of channel structures 750 can form a staggered array form. In some implementations, the array of channel structures 750 can include a plurality of rows of channel structures 750. Each row of channel structures 750 can be aligned along the word line direction (X-direction). Adjacent rows of channel structures 750 can be misaligned. In some implementations, the array of channel structures 750 can include a plurality of columns of channel structures 750. Each column of channel structures 750 can be aligned along the bit line direction (Y-direction). Adjacent columns of channel structures 750 can be misaligned.

In some implementations, fabricating process for forming the channel structures 750 and dummy channel structures 755 can include forming an epitaxial layer at a bottom of each channel hole/dummy channel hole. In some implementations, the epitaxial layer can be a polycrystalline silicon (polysilicon) layer formed by using a selective epitaxial growth (SEG) process. For example, an SEG pre-clean process can be performed to clean the multiple channel holes. A following deposition process can be performed to form a polysilicon layer at the bottom of each channel hole. In some implementations, any suitable doping process, such as an ion metal plasma (IMP) process, can be performed on the polysilicon layer to form the epitaxial layer. In some implementations, the epitaxial layer may not be directly formed on the surface of substrate 710. One or more layers can be formed between the epitaxial layer and the substrate 710. That is, the epitaxial layer overlays the substrate 710.

In some implementations, fabrication processes to form the channel structures 750 and dummy channel structures 755 can include forming an optional high-K dielectric layer (not shown) on the sidewall of each channel hole, and forming a functional layer to cover the high-K dielectric layer. The functional layer can be a composite dielectric layer, such as a combination of a barrier layer, a storage layer, and a tunneling layer. The high-K dielectric layer, the functional layer, including the barrier layer, the storage layer, and the tunneling layer, can be formed by one or more thin film deposition processes, such as ALD, CVD, PVD, any other suitable processes, or any combination thereof.

In some implementations, the barrier layer and/or the high-K dielectric layer can be formed between the storage layer and the sidewall of the channel hole/dummy channel hole. The barrier layer and/or the high-K dielectric layer can be used for blocking the outflow of the electronic charges. In some implementations, the barrier layer can be a silicon oxide layer or a combination of silicon oxide/silicon nitride/silicon oxide (ONO) layers. In some implementations, the high-K dielectric layer includes any suitable high dielectric constant (high k-value) dielectrics (e.g., aluminum oxide).

The storage layer can be formed between the tunneling layer and the barrier layer. Electrons or holes from the channel layer can tunnel to the storage layer through the tunneling layer. The storage layer can be used for storing electronic charges (electrons or holes) for memory operation. The storage or removal of charge in the storage layer can impact the on/off state and/or a conductance of the semiconductor channel. The storage layer can include one or more films of materials including, but are not limited to, silicon nitride, silicon oxynitride, a combination of silicon oxide and silicon nitride, or any combination thereof. In some implementations, the storage layer can include a nitride layer formed by using one or more deposition processes.

The tunneling layer can be formed on the sidewall of the storage layer. The tunneling layer can be used for tunneling electronic charges (electrons or holes). The tunneling layer can include dielectric materials including, but not limited to, silicon oxide, silicon nitride, silicon oxynitride, or any combination thereof. In some implementations, the tunneling layer can be an oxide layer formed by using a deposition process.

Referring back to FIG. 6, the method proceeds to operation 615, in which the sacrificial filling structures can be removed, and a gate line slit (GLS) structure can be formed in the stack structure. The GLS structure extends vertically through the stack structure and laterally along the first lateral direction. In some implementations, operation 615 may include: operation 6151, forming a dielectric structure extending vertically through the stack structure and located at a boundary between the array region and the contact region; operation 6152, forming a first GLS structure segment laterally extending from the dielectric structure to the contact region along the first lateral direction; and operation 6153, forming a second GLS structure segment laterally extending from the dielectric structure to the array region along the first lateral direction.

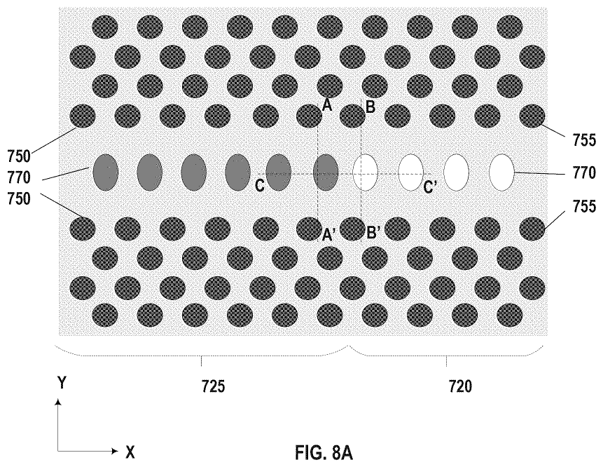

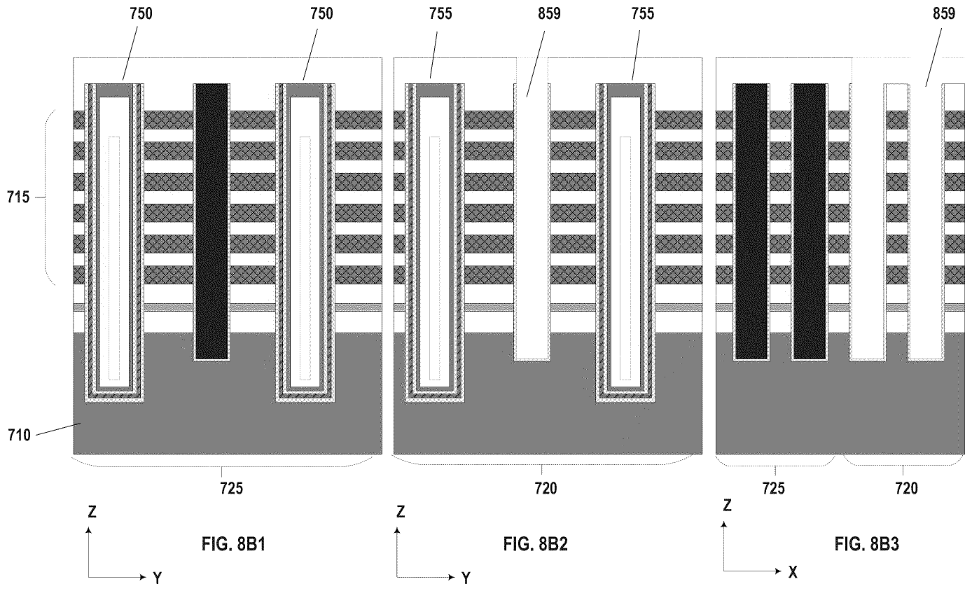

FIGS. 8A, 8B1-8B3, 9A, 9B1-9B3, 10A, 10B1-10B3, 11A, 11B1-11B3, 12A, 12B1-B3, 13A1-13A3, 14A, 14B1-14B3, 15A, 15B1-15B3, 16A1-16A3, 17A, 17B1-17B3, 18A, 18B1-18B3, 19A, 19B1-19B3, 20A, 20B 1-20B3, 21A, and 2 1B1-21B3 illustrate schematic diagram of the 3D structure during certain stages of operation 615 according to some implementations of the present disclosure.

In some implementations, the sacrificial filling structures 760 in the first through holes 771 in the contact region 720 can be removed to form a plurality of first slit openings 859 in the contact region 720. FIG. 8A illustrates a schematic diagram of the 3D structure in a top-down perspective view, corresponding to FIG. 7C after removing the plurality of sacrificial filling structures 760, without affecting the plurality of channel structures 750 in the array region 725 and the plurality of dummy channel structure 755 in the contact region 720 at certain stage of operation 610. FIG. 8B1 illustrates a schematic diagram of a portion of the 3D structure in a cross-sectional side view along the AA′ line shown in FIG. 8A, according to some implementations of the present disclosure. FIG. 8B2 illustrates a schematic diagram of a portion of the 3D structure in a cross-sectional side view along the BB′ line shown in FIG. 8A, according to some implementations of the present disclosure. FIG. 8B3 illustrates a schematic diagram of a portion of the 3D structure in a cross-sectional side view along the CC′ line shown in FIG. 8A, according to some implementations of the present disclosure.

As shown in FIGS. 8A and 8B1-8B3, in some implementations, the plurality of first slit openings 859 can be formed by forming a mask layer (not shown) over the stack structure 715 in the contact region 720 and patterning the mask using, e.g., photolithography. A suitable etching process, e.g., dry etch and/or wet etch, can be performed to remove the sacrificial filling structures 760 to form the plurality of first slit openings 859.

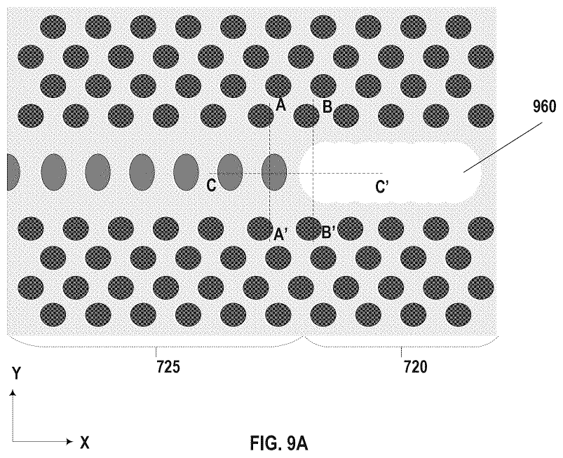

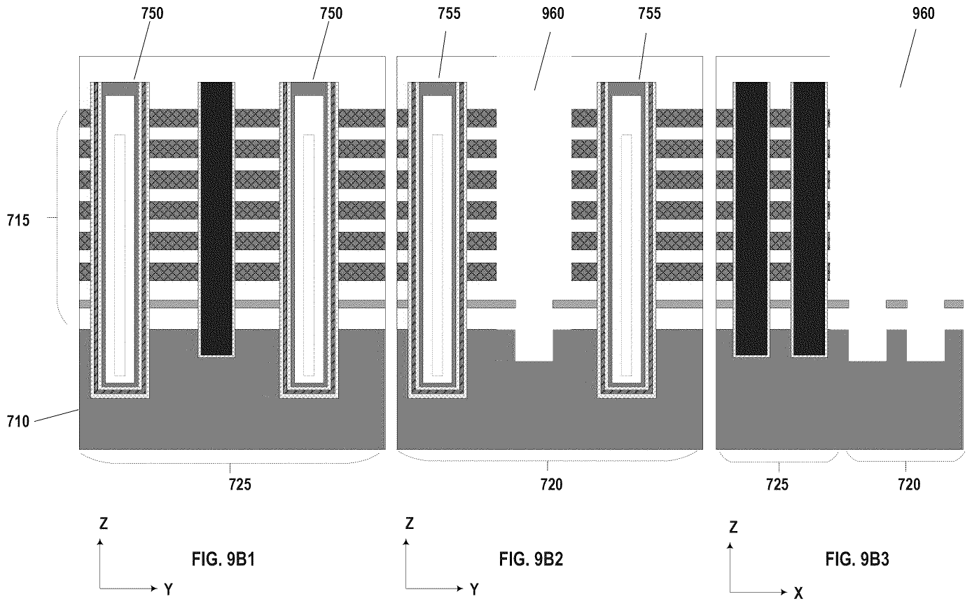

In some implementations, the plurality of first slit openings 859 can be enlarged, such that the plurality of first slit openings 859 are connected with each other to form a first trench 960 as shown in FIGS. 9A and 9B1-9B3. FIG. 9A illustrates a schematic diagram of the 3D structure in a top-down perspective view, corresponding to FIG. 8A after enlarging the plurality of first slit openings 859, without affecting the plurality of channel structures 750 in the array region 725 and the plurality of dummy channel structure 755 in the contact region 720 at certain stage of operation 610. FIG. 9B1 illustrates a schematic diagram of a portion of the 3D structure in a cross-sectional side view along the AA′ line shown in FIG. 9A, according to some implementations of the present disclosure. FIG. 9B2 illustrates a schematic diagram of a portion of the 3D structure in a cross-sectional side view along the BB′ line shown in FIG. 9A, according to some implementations of the present disclosure. FIG. 9B3 illustrates a schematic diagram of a portion of the 3D structure in a cross-sectional side view along the CC′ line shown in FIG. 9A, according to some implementations of the present disclosure.

A suitable etching process, e.g., dry etch and/or wet etch, can be performed to enlarge the plurality of first slit openings 859 to form the first trench 960. The first trench 960 can each extend vertically penetrate through the stack structure 715 into the substrate 710. In some implementations, a doped region (not shown) can be formed at a bottom of the first trench 960 in the substrate 710 by using any suitable doping process, such as ion implantation and/or thermal diffusion through the first trench 960. The dopant in the doped region can be any suitable N+or P+ions. After forming a conductive wall in the first trench 960 in a subsequent process, the lower end of each conductive wall can be in contact with a corresponding doped region.

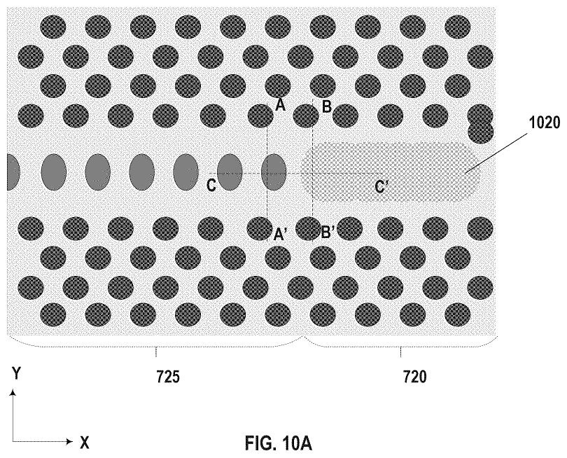

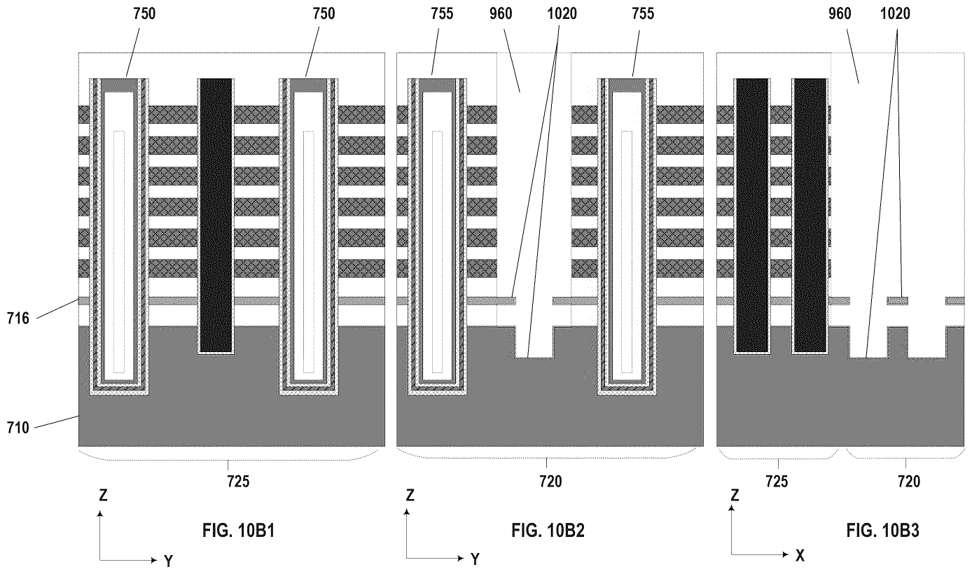

In some implementations, a first oxidation process can be performed to oxide the substrate 710 and the semiconductor layer 716 exposed by the first trench 960 to form first oxide layers 1020, as shown in FIGS. 10A and 10B1-10B3. FIG. 10A illustrates a schematic diagram of the 3D structure in a top-down perspective view, corresponding to FIG. 9A after forming the first oxide layers 1020, without affecting the plurality of channel structures 750 in the array region 725 and the plurality of dummy channel structure 755 in the contact region 720 at certain stage of operation 610. FIG. 10B1 illustrates a schematic diagram of a portion of the 3D structure in a cross-sectional side view along the AA′ line shown in FIG. 10A, according to some implementations of the present disclosure. FIG. 10B2 illustrates a schematic diagram of a portion of the 3D structure in a cross-sectional side view along the BB′ line shown in FIG. 10A, according to some implementations of the present disclosure. FIG. 10B3 illustrates a schematic diagram of a portion of the 3D structure in a cross-sectional side view along the CC′ line shown in FIG. 10A, according to some implementations of the present disclosure.

The first oxidation process can be performed by exposing the substrate to an oxygen-containing atmosphere at elevated temperatures. The temperature and duration of the oxidation process can be controlled to achieve the desired thickness of the oxide layers. In some implementations, the first oxidation process may involve dry oxidation or wet oxidation, depending on the specific requirements of the application. Dry oxidation can be used to form a denser and thinner oxide layers, while wet oxidation can produce thicker oxide layers more rapidly. The first oxide layers 1020 may serve as a protective barrier for the substrate 710 during subsequent processing steps, preventing contamination or damage. In some implementations, the semiconductor layer 716 exposed by the first trench 960 can also be oxidized during the oxidation of the substrate 710, as shown in FIG. 10B2 and FIG. 10B3.

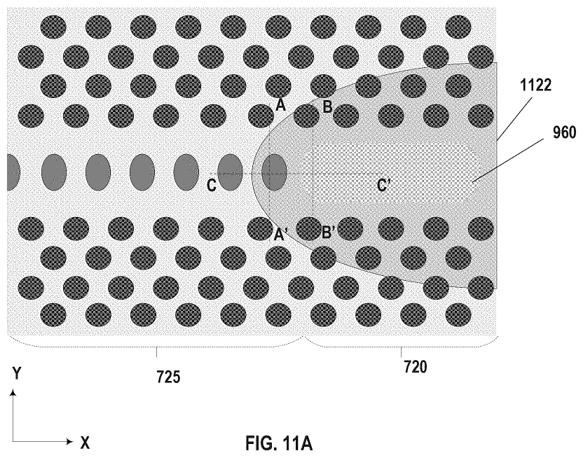

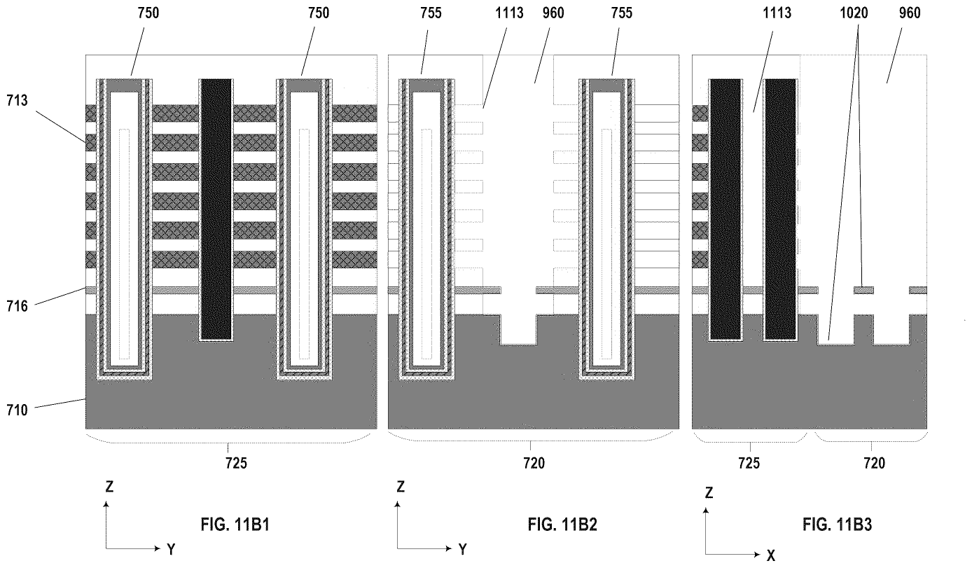

In some implementations, as shown in FIGS. 11A and 11B1-11B3, portions of the nitride layers 713 in the contact region 720 and portions of the nitride layers 713 in the array region 725 exposed by the first trench 960 can be removed to form first gaps 1113. FIG. 11A illustrates a schematic diagram of the 3D structure in a top-down perspective view, corresponding to FIG. 10A after removing the nitride layers 713 in the fan-shaped region 1122. The fan-shaped region 1122 is mainly located in the contact region 720 and partially located in the array region 725. FIG. 11B1 illustrates a schematic diagram of a portion of the 3D structure in a cross-sectional side view along the AA′ line shown in FIG. 11A, according to some implementations of the present disclosure. FIG. 11B2 illustrates a schematic diagram of a portion of the 3D structure in a cross-sectional side view along the BB′ line shown in FIG. 11A, according to some implementations of the present disclosure. FIG. 11B3 illustrates a schematic diagram of a portion of the 3D structure in a cross-sectional side view along the CC′ line shown in FIG. 11A, according to some implementations of the present disclosure.

A selective removal of nitride layers 713 in the fan-shaped region 1122 can be performed using a dry etching technique, such as reactive ion etching (RIE), to ensure precision and minimize damage to surrounding structures. That is, only the nitride layers 713 in the contact region 720 exposed by first trench 960 are removed, while the nitride layers 713 in the array region 725, the substrate 710, the semiconductor layer 716, and the first oxide layers 1020, etc., are not affected. The etching parameters, including gas composition and etching time, can be adjusted to target only the exposed nitride layers, leaving other materials intact. Since the removal of nitride layers 713 is through the first trench 960, and the first trench is located in the contact region 720, so the majority of removal of nitride layers 713 is occurred in the contact region 720. In addition, nitride layers 713 in the array region 725 exposed by the first trench 960 can also be removed as shown in FIG. 11B3. The selective removal of nitride layers 713 does not affect the channel structure 750 in the array region 725 and the dummy channel structure 755 in the contact region, as shown in FIG. 11B1 and FIG. 11B2.

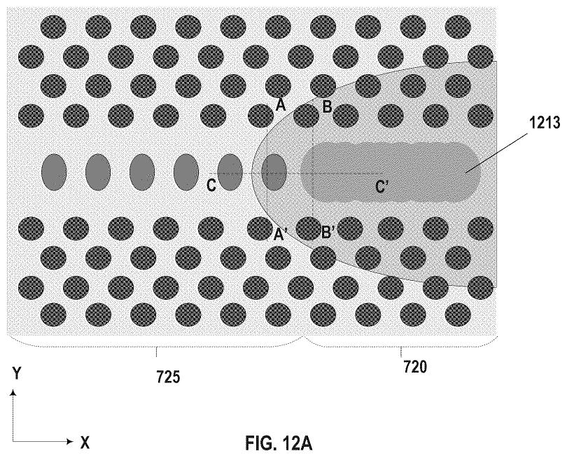

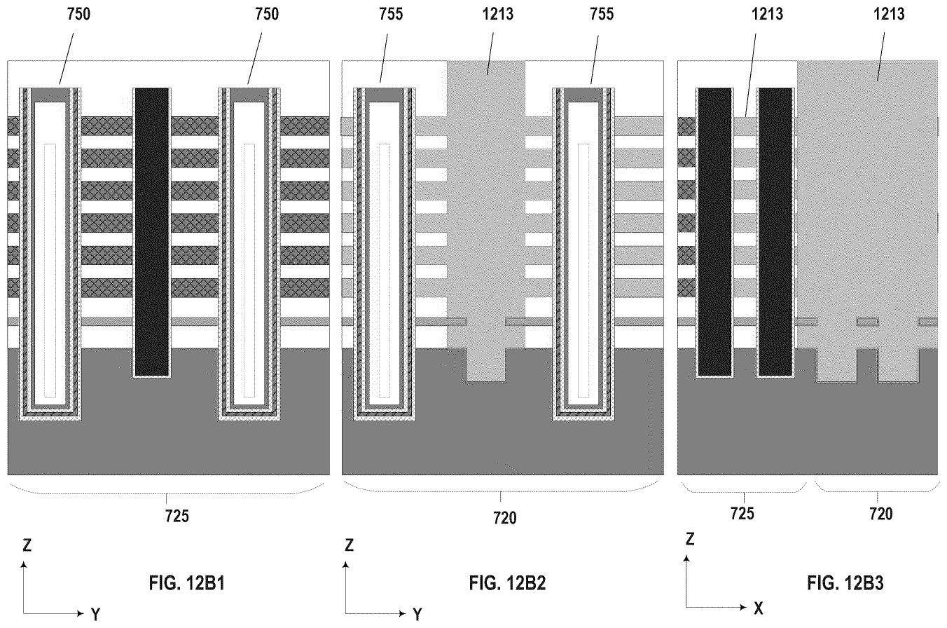

In some implementations, after forming the first gaps 1113, the first gaps 1113 and the first trench 960 can be filled with a sacrificial material to a form a sacrificial structure 1213, as shown in FIGS. 12A and 12B1-12B3. FIG. 12A illustrates a schematic diagram of the 3D structure in a top-down perspective view, corresponding to FIG. 11A after forming the sacrificial structure 1213, without affecting the plurality of channel structures 750 in the array region 725 and the plurality of dummy channel structure 755 in the contact region 720 at certain stage of operation 610. FIG. 12B1 illustrates a schematic diagram of a portion of the 3D structure in a cross-sectional side view along the AA′ line shown in FIG. 12A, according to some implementations of the present disclosure. FIG. 12B2 illustrates a schematic diagram of a portion of the 3D structure in a cross-sectional side view along the BB′ line shown in FIG. 12A, according to some implementations of the present disclosure. FIG. 12B3 illustrates a schematic diagram of a portion of the 3D structure in a cross-sectional side view along the CC′ line shown in FIG. 12A, according to some implementations of the present disclosure.

Forming the sacrificial structure can be performed by a deposition process, such as chemical vapor deposition (CVD), ensuring uniform coverage across the gaps. The sacrificial material can be a material such as polysilicon or amorphous carbon, depending on the subsequent removal process. Once deposited, the sacrificial material may undergo planarization, such as chemical mechanical polishing (CMP), to ensure that the surface is level with surrounding structures, as shown in FIG. 12B1-12B3. In some implementations, during the formation of the sacrificial structure, the plurality of channel structures 750 in the array region 725 and the plurality of dummy channel structure 755 in the contact region 720 are not affected, as shown in FIG. 12B1 and FIG. 12B2.

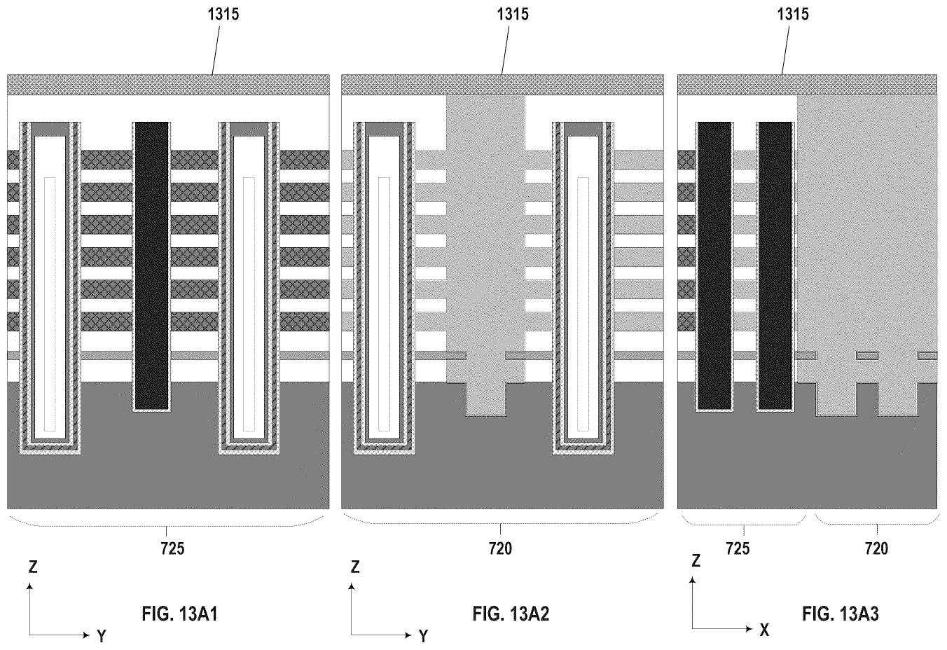

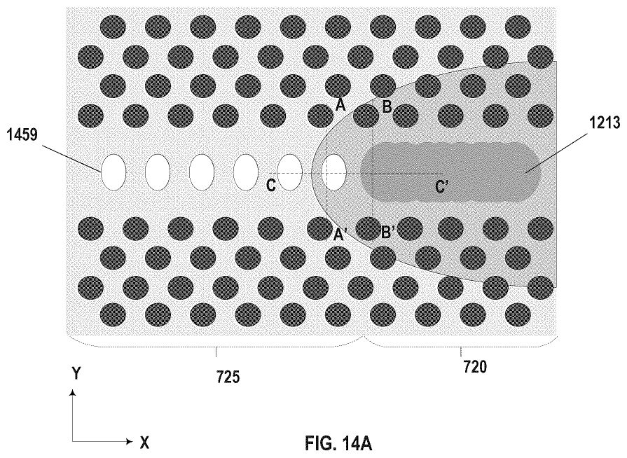

In some implementations, after forming the sacrificial structure 1213, a cap layer 1315 may be formed to cover both the contact region 720 and the array region 725, as shown in FIG. 13A1-13A3, which illustrate schematic diagrams of the 3D structure in cross-sectional side views, respectively corresponding to FIG. 12B1-12B3 after forming the cap layer 1315. The cap layer 1315 may be formed by performing a deposition of a material such as silicon oxynitride (SiON) through a chemical vapor deposition (CVD) process. The CVD process can be carried out under specific conditions to achieve a desired thickness and uniformity of the cap layer 1315, ensuring effective coverage across both regions. The cap layer 1315 provides protection during subsequent processing, acting as a barrier against contamination and serving as a structural support.

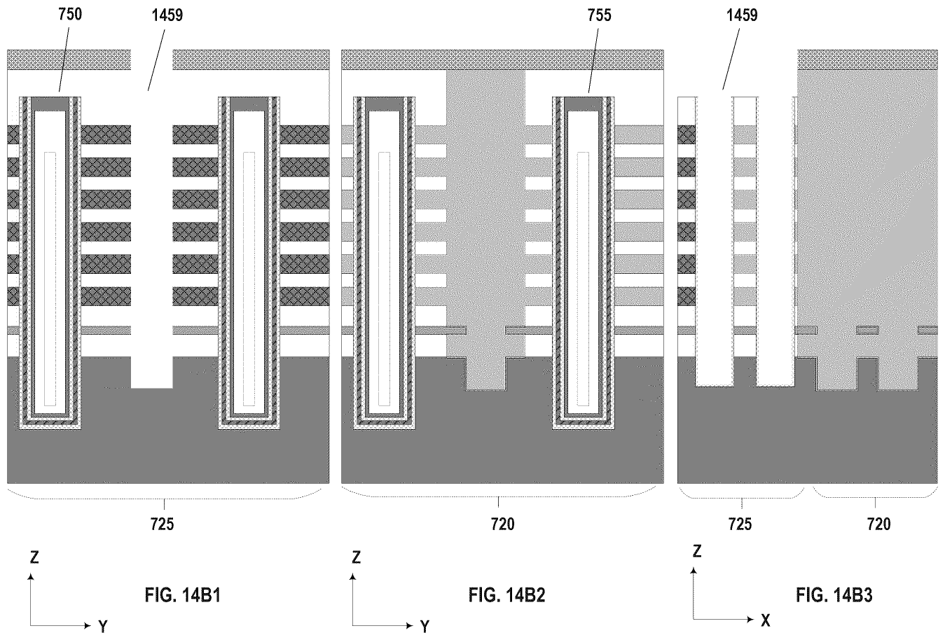

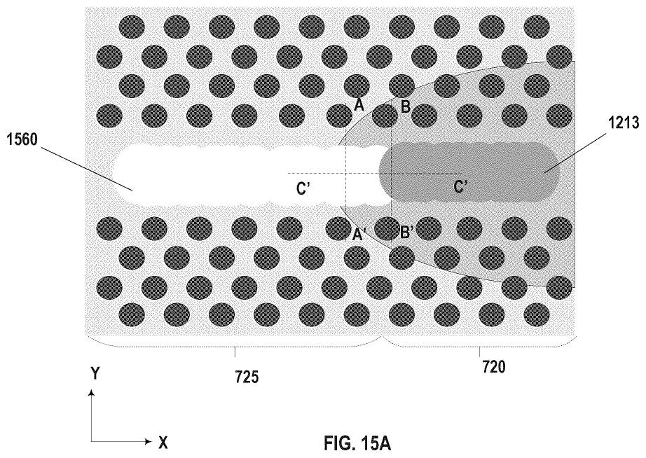

In some implementations, the sacrificial filling structures 760 in the second through holes 773 in the array region 725 can be removed to form a plurality of second slit openings 1459 in the array region 725. FIG. 14A illustrates a schematic diagram of the 3D structure in a top-down perspective view, corresponding to FIG. 12A after forming the plurality of second slit openings 1459, without affecting the plurality of channel structures 750 in the array region 725 and the plurality of dummy channel structure 755 in the contact region 720, at certain stage of operation 610. FIG. 14B1 illustrates a schematic diagram of a portion of the 3D structure in a cross-sectional side view along the AA′ line shown in FIG. 14A, according to some implementations of the present disclosure. FIG. 14B2 illustrates a schematic diagram of a portion of the 3D structure in a cross-sectional side view along the BB′ line shown in FIG. 14A, according to some implementations of the present disclosure. FIG. 14B3 illustrates a schematic diagram of a portion of the 3D structure in a cross-sectional side view along the CC′ line shown in FIG. 12A, according to some implementations of the present disclosure.

The plurality of second slit openings 1459 can be formed by forming a mask layer (not shown) over the cap layer 1315 in the array region 725 and patterning the mask using, e.g., photolithography. A suitable etching process, e.g., dry etch and/or wet etch, can be performed to remove the sacrificial filling structures 760 in the array region 725 to form the plurality of second slit openings 1459 as shown in FIG. 14A, FIG. 14B1, and FIG. 14B3. The etching process can be selective to the removal of only the sacrificial filing structure, such that other parts of the 3D structure are not affected. For example, the channel structure 750 in the array region and the dummy channel structure 755 in the contact region are not affected by the removal of the sacrificial filling structure 760 as shown in FIG. 14B1 and FIG. 14B2.

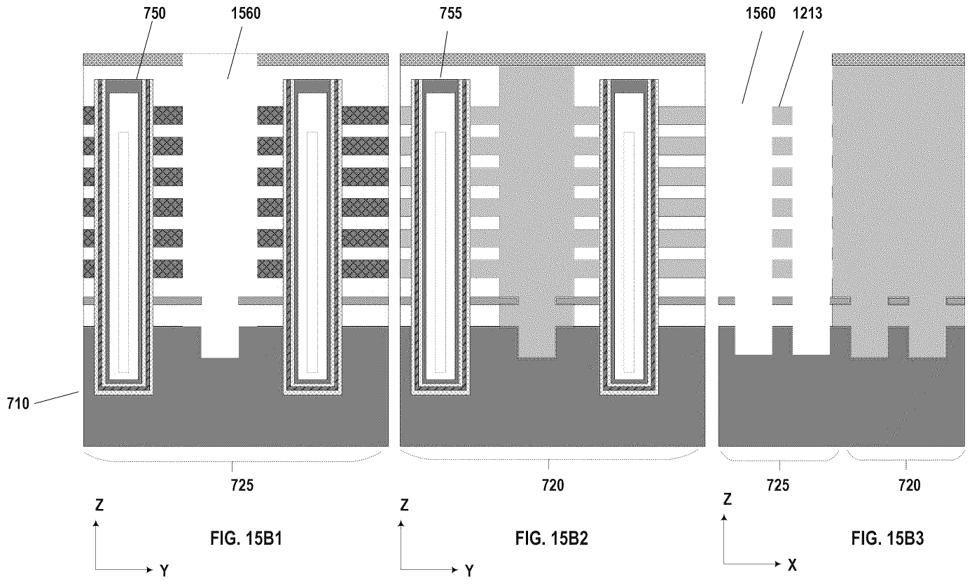

In some implementations, the plurality of second slit openings 1459 can be etched and enlarged, such that the second slit openings 1459 are connected with each other to form a second trench 1560 in the array region 725. FIG. 15A illustrates a schematic diagram of the 3D structure in a top-down perspective view, corresponding to FIG. 14A after forming the second trench 1560, without affecting the plurality of channel structures 750 in the array region 725 and the plurality of dummy channel structure 755 in the contact region 720, at certain stage of operation 610. FIG. 15B1 illustrates a schematic diagram of a portion of the 3D structure in a cross-sectional side view along the AA′ line shown in FIG. 15A, according to some implementations of the present disclosure. FIG. 15B2 illustrates a schematic diagram of a portion of the 3D structure in a cross-sectional side view along the BB′ line shown in FIG. 15A, according to some implementations of the present disclosure. FIG. 15B3 illustrates a schematic diagram of a portion of the 3D structure in a cross-sectional side view along the CC′ line shown in FIG. 15A, according to some implementations of the present disclosure. The second trench 1560 can extend vertically and penetrate through the stack structure 715 into the substrate 710.

A suitable etching process, e.g., dry etch and/or wet etch, can be performed to enlarge the second slit openings 1459 until the second trench 1560 is formed to expose the sacrificial structure 1213 and the substrate 710. In some implementations, the etching process for enlarging the second slit openings 1459 can be stopped by the sacrificial structure 1213 when the etching process is fully selective. That is, the second trench 1560 stops at a side surface of the sacrificial structure 1213 without affecting the sacrificial structure 1213 as shown in FIG. 15A. In some implementations, a doped region (not shown) can be formed at a bottom of the second trench 1560 in the substrate 710 by using any suitable doping process, such as ion implantation and/or thermal diffusion through the second trench 1560. The dopant in the doped region can be any suitable N+ or P+ ions. After forming a conductive wall in the second trench 1560 in a subsequent process, the lower end of each conductive wall can be in contact with a corresponding doped region.

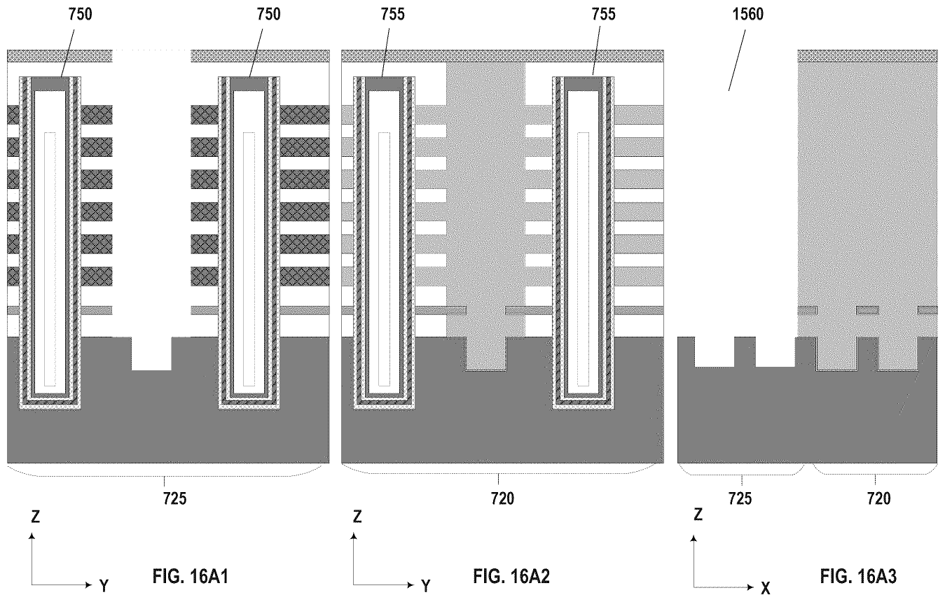

In some implementations, during the enlargement of the second slit opening 1459 to form the second trench 1560, as shown in FIG. 15B3, portions of the sacrificial structure 1213 in the array region 725 remain intact because only the sacrificial filling structures 760 are selectively removed. The retained sacrificial material can then be removed by performing a recess process. As shown in FIG. 16A1-16A3, the remaining portions of the sacrificial structure 1213 in the second trench 1560 are removed, while the channel structure 750 in the array region 725 and the dummy channel structure 755 in the contact region 720 remain unaffected, as illustrated in FIG. 16A1-16A2.

The recess process involves selective etching techniques, which may utilize either wet etching or dry etching, such as reactive ion etching (RIE). These techniques carefully remove the sacrificial material without damaging surrounding structures. The etching parameters, including etching agents, pressure, and etching time, are optimized to ensure precise control over the removal of the sacrificial material.

During the recess process, a side surface of the sacrificial structure 1213 in the first trench 960 can also be etched. The etching may form a curved surface for the sacrificial structure 1213, which may be convex towards the array region or towards the contact region, depending on the specific etching conditions, such as whether wet or dry etching is used, as well as the duration of the etching process.

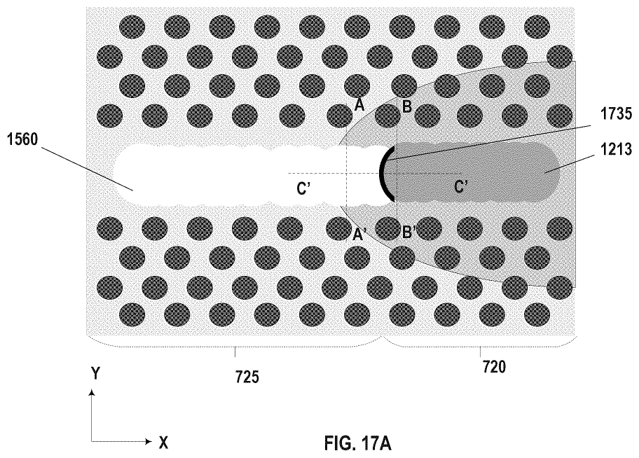

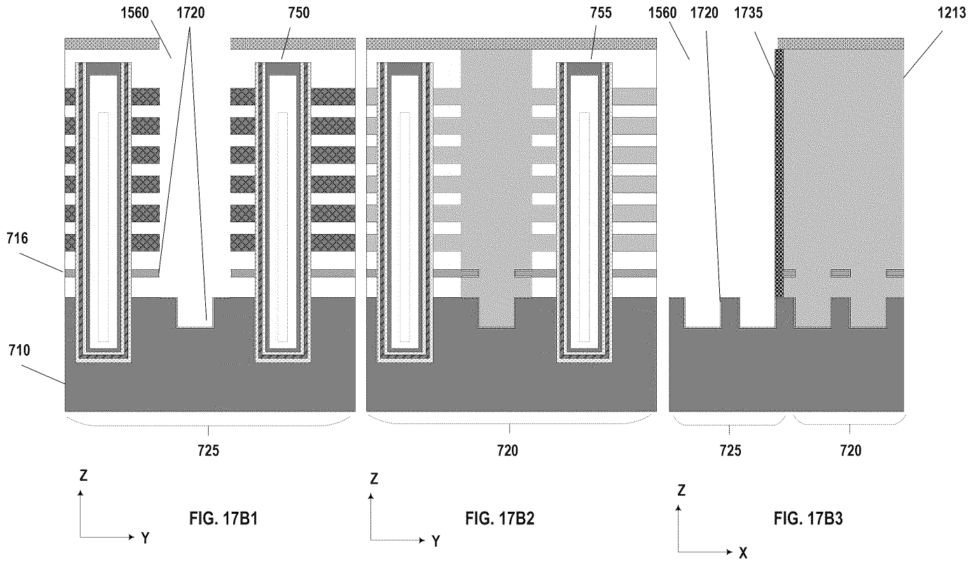

In some implementations, a second oxidation process can be performed to oxidize a side surface of the sacrificial structure 1213 exposed by the second trench 1560 to form an intermedia sub-layer 1735, as shown in FIGS. 17A and 17B1-17B3. The second oxidation process can be performed by exposing the sacrificial structure 1213 to an oxygen-containing atmosphere at elevated temperatures. The temperature and duration of the oxidation process can be controlled to achieve the desired thickness of the oxide layer. In some implementations, the second oxidation process may involve dry oxidation or wet oxidation, depending on the specific requirements of the application. Dry oxidation can be used to form a denser and thinner oxide layer, while wet oxidation can produce a thicker layer more rapidly. Depending on the oxidation conditions, the thickness of the intermedia sub-layer 1735 can be in a range from about 30 nm to about 200 nm. In addition to the oxidation of the side surface of the sacrificial structure 1213, in some implementations, surfaces of the substrate 710 and the semiconductor layer 716 exposed by the second trench 1560 can be oxidized to form second oxide layers 1720, as shown in FIG. 17B1 and FIG. 17B3. The channel structure 750 in the array region 725 and the dummy channel structure 755 in the array region are not affected by oxidation, as shown in FIG. 17B1 and FIG. 17B2.

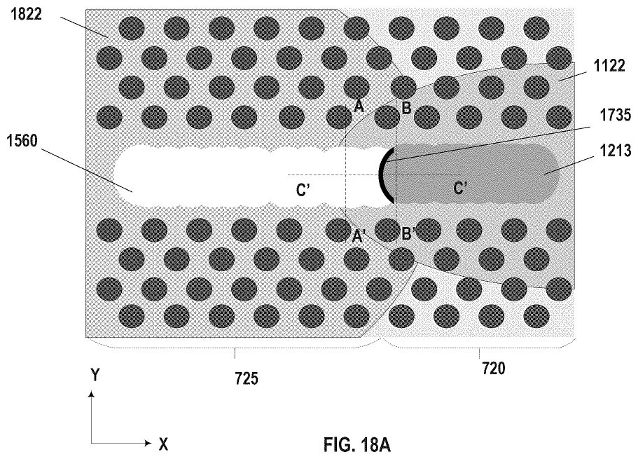

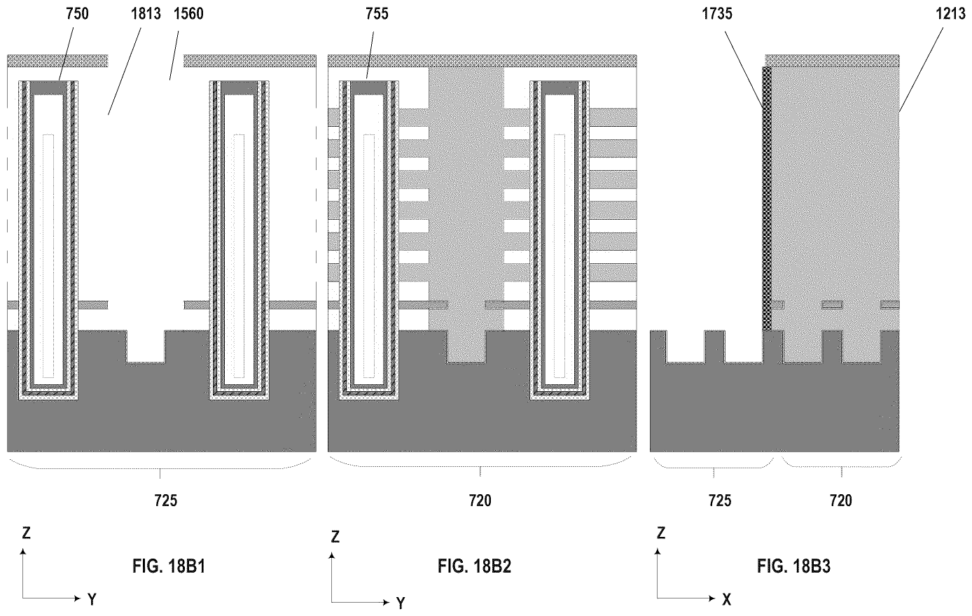

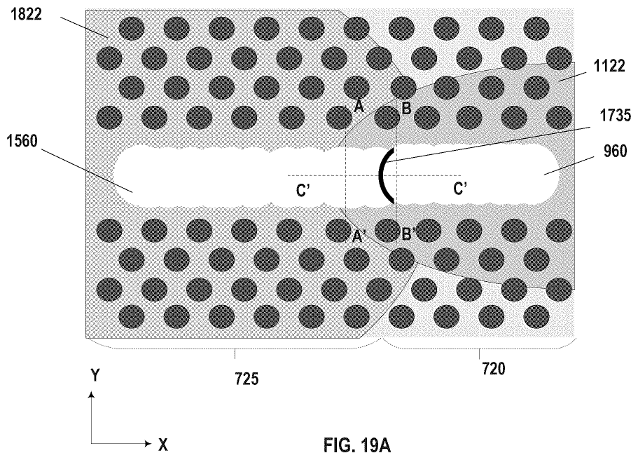

In some implementations, the nitride layers 713 in the array region 725 exposed by the second trench 1560 can be removed to form second gaps 1813, as shown in FIGS. 18A and 18B1-18B3. FIG. 18A illustrates a schematic diagram of the 3D structure in a top-down perspective view, corresponding to FIG. 15A after removing nitride layers through the second trench 1560, without affecting the plurality of channel structures 750 in the array region 725 and the plurality of dummy channel structure 755 in the contact region 720 at certain stage of operation 610. FIG. 18B1 illustrates a schematic diagram of a portion of the 3D structure in a cross-sectional side view along the AA′ line shown in FIG. 18A, according to some implementations of the present disclosure. FIG. 18B2 illustrates a schematic diagram of a portion of the 3D structure in a cross-sectional side view along the BB′ line shown in FIG. 18A, according to some implementations of the present disclosure. FIG. 18B3 illustrates a schematic diagram of a portion of the 3D structure in a cross-sectional side view along the CC′ line shown in FIG. 18A, according to some implementations of the present disclosure.

A selective removal process can be performed using a dry etching technique, such as reactive ion etching (RIE), to ensure precision and minimize damage to surrounding structures. The etching parameters, including gas composition and etching time, can be adjusted to target only the exposed nitride layers 713, leaving other materials intact. For example, the channel structures 750 in the array region 725 as shown in FIG. 18B1, the dummy channel structure 755 in the contact region 720 as shown in FIG. 18B2, and the intermedia sub-layer 1735 on the side surface of the sacrificial structure 1213 as shown in FIG. 18B3 are not affected by the removal of the nitride layers 713. Since the removal of nitride layers 713 is through the second trench 1560, and the second trench 1560 is located in the array region 725, the removal of nitride layers 713 mainly occurs in the array region 725 as indicated by the shaded-region 1822 shown in FIG. 18A. After performing selective removal of nitride layers 713 through the second trench 1560, nitride layers 713 in the shaded-region 1822 and the fan-shaped region 1122 are removed as shown in FIG. 18A.

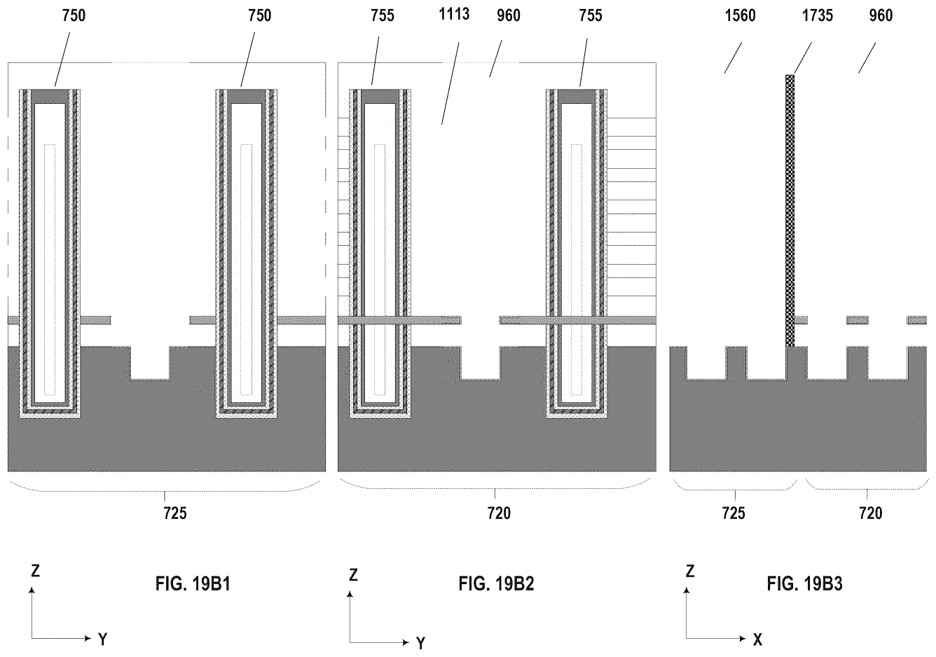

In some implementations, the sacrificial structure 1213 may be selectively removed without affecting the intermedia sub-layer 1735. FIG. 19A illustrates a schematic diagram of the 3D structure in a top-down perspective view, corresponding to FIG. 18A after removing the sacrificial structure 1213, without affecting the plurality of channel structures 750 in the array region 725 and the plurality of dummy channel structure 755 in the contact region 720. FIG. 19B1 illustrates a schematic diagram of a portion of the 3D structure in a cross-sectional side view along the AA′ line shown in FIG. 19A, according to some implementations of the present disclosure. FIG. 19B2 illustrates a schematic diagram of a portion of the 3D structure in a cross-sectional side view along the BB′ line shown in FIG. 19A, according to some implementations of the present disclosure. FIG. 19B3 illustrates a schematic diagram of a portion of the 3D structure in a cross-sectional side view along the CC′ line shown in FIG. 19A, according to some implementations of the present disclosure.

This selective removal of the sacrificial structure 1213 can be performed using a suitable etching process that targets the specific material of the sacrificial structure 1213, while leaving the channel structure 750 in the array region 725 (as shown in FIG. 19B1), the dummy channel structure 755 in the contact region 720 (as shown in FIG. 19B2), and the intermedia sub-layer 1735, formed by oxidizing the side surface of the sacrificial structure 1213 on the boundary of array region 725 and contact region 720, unaffected, as shown in FIGS. 19A and 19B3. Since the sacrificial structure 1213 is formed within the first trench 960 and the first gaps 1113, its removal will restore the first trench 960 and the first gaps 1113 as shown in FIGS. 19A and 19B2-19B3. After selectively removing the sacrificial structure 1213, the intermedia sub-layer 1735 is retained intact with a curved wall structure that is convex toward the array region as shown in FIG. 19A and FIG. 19B3. In some implementations, the curved wall structure can be convex toward the contact region (not shown).

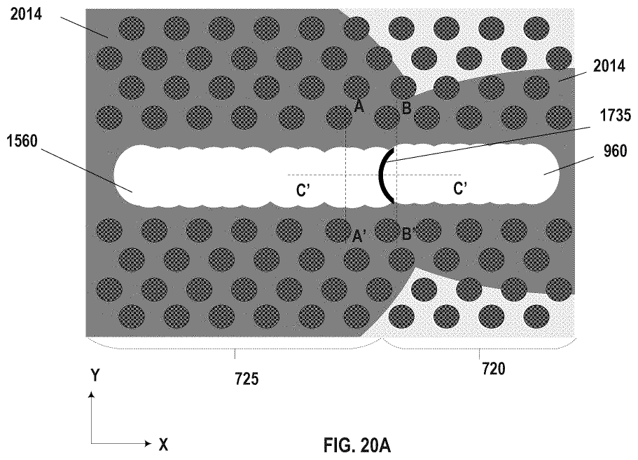

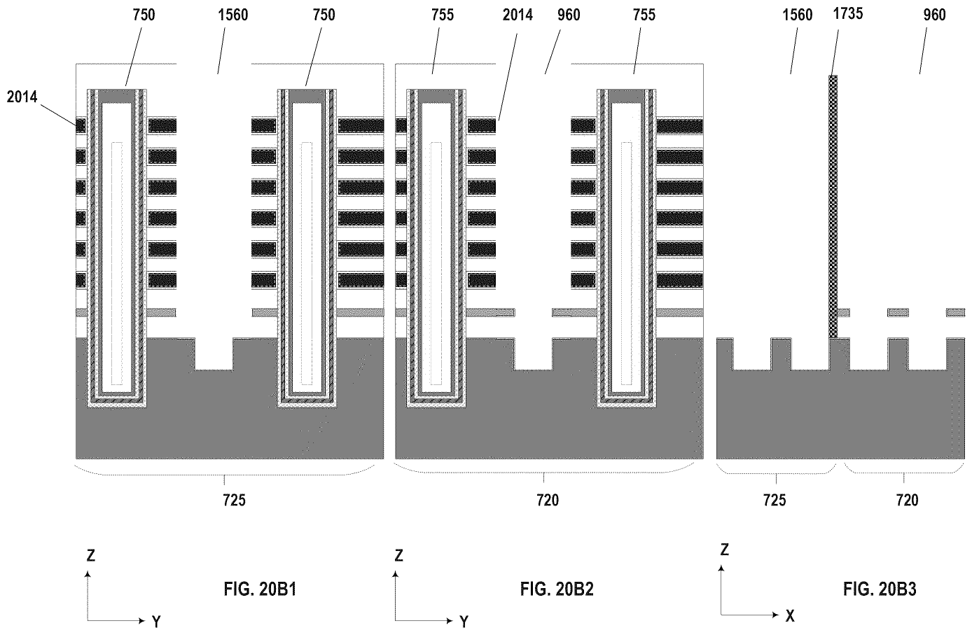

In some implementations, after removing the sacrificial structure 1213, the restored first gaps 1113 and first trench 960 (as shown in FIG. 19B2), along with the second gaps 1813 (as shown in FIG. 18B1) can be filled with a conductive material to form a plurality of conductive layers 2014 as show in FIGS. 20A and 20B1-20B2. The conductive material may be deposited using a method such as chemical vapor deposition (CVD), physical vapor deposition (PVD), or atomic layer deposition (ALD), depending on the specific requirements of the process. Suitable conductive materials can include metals such as tungsten (W), copper (Cu), or aluminum (Al), or other conductive compounds like titanium nitride (TiN). The plurality of conductive layers 2014 may be served as word lines and contribute to establishing electrical connections between various components of the 3D device.

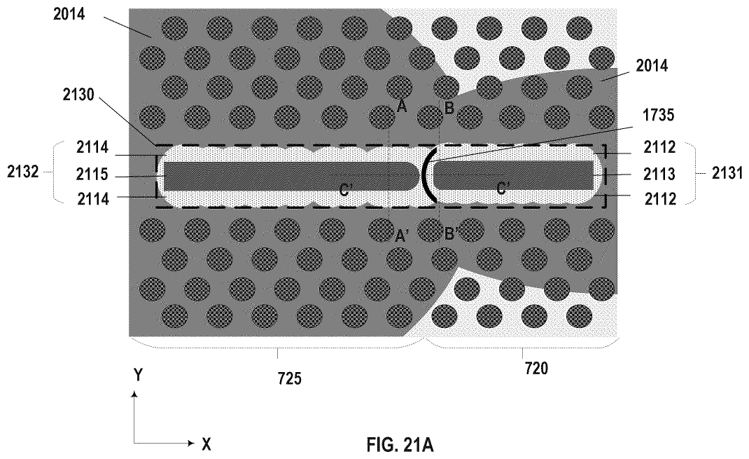

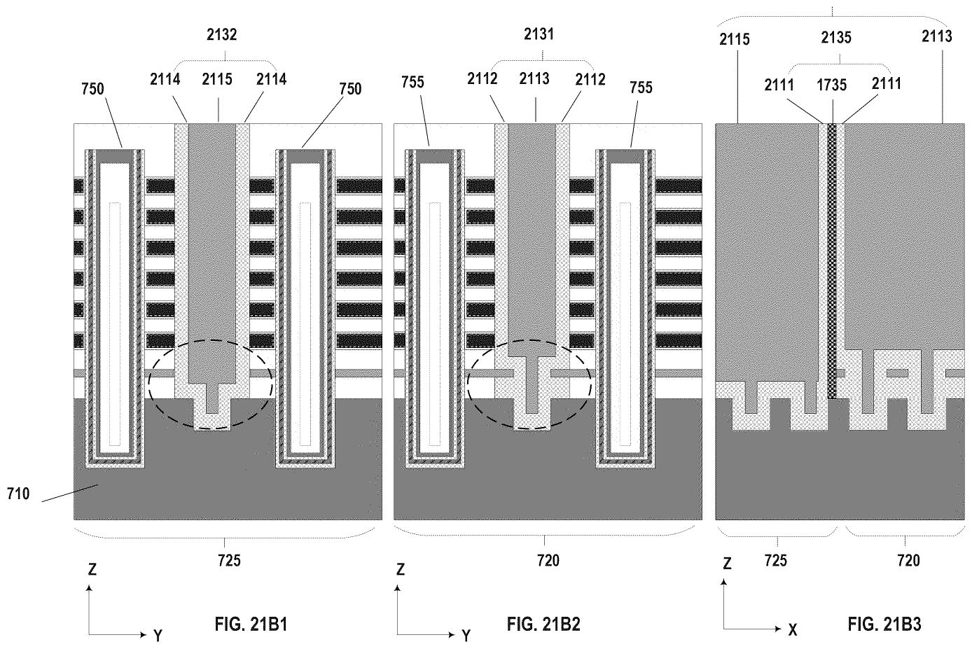

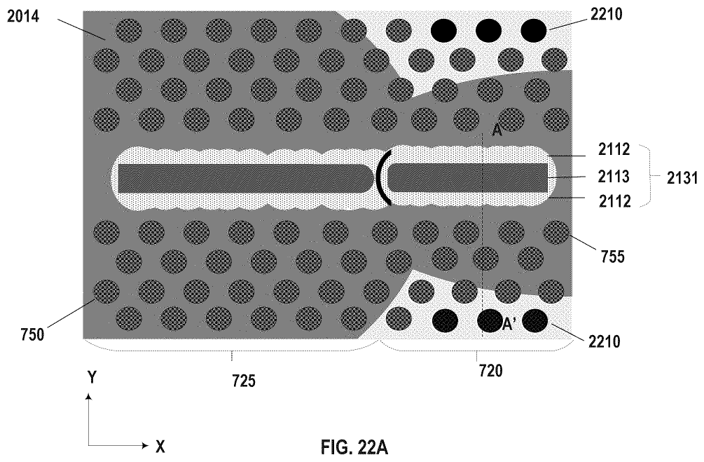

Referring back to FIG. 6, the method proceeds to operation 615, in which a GLS structure is formed extending vertically through the stack structure and laterally along the first lateral direction. The operation 615 may include: operation 6151, forming a dielectric structure extending vertically through the stack structure and located at a boundary between the array region and the contact region; operation 6152, forming a first GLS structure segment laterally extending from the dielectric structure to the contact region along the first lateral direction; and operation 6153, forming a second GLS structure segment laterally extending from the dielectric structure to the array region along the first lateral direction. FIG. 21A illustrates a schematic diagram of the 3D structure during operation 615 in a top-down perspective view, according to some implementations of the present disclosure. FIG. 21B illustrates a schematic diagram of a portion of the 3D structure in a cross-sectional side view along the AA′ line shown in FIG. 21A, according to some implementations of the present disclosure. FIG. 21C illustrates a schematic diagram of a portion of the 3D structure in a cross-sectional side view along the BB′ line shown in FIG. 21A, according to some implementations of the present disclosure. FIG. 21D illustrates a schematic diagram of a portion of the 3D structure in a cross-sectional side view along the CC′ line shown in FIG. 21A, according to some implementations of the present disclosure.

As shown in FIGS. 21A-21E, a GLS structure 2130 including a first GLS structure segment 2131, a second GLS structure segment 2132, and a dielectric structure 2135 can be formed. The first GLS structure segment 2131 can be formed in the first trench 960 in the contact region 720, the second GLS structure segment 2132 can be formed in the second trench 1560 in the array region 725, and the dielectric structure 2135 can be formed at the boundary of the array region 725 and the contact region 720.

In some implementations, the operation 6151 for forming the dielectric structure 2135 can include depositing a second insulating layer 2111 on both sides of the intermedia sub-layer 1735 along the first lateral direction (i.e., X-direction as shown in FIG. 21B3). The second insulating layer 2111 can be deposited using a material the same as that of the intermedia sub-layer 1735. The second insulating layer 2111 can also be deposited using a material different from that of the intermedia sub-layer 1735. This deposition process can be performed using techniques such as chemical vapor deposition (CVD), atomic layer deposition (ALD), or physical vapor deposition (PVD), depending on the material used and the desired layer thickness. These methods ensure uniform coverage along both sides of the intermedia sub-layer 1735, achieving precise control over the insulating properties and layer thickness required for the dielectric structure 2135.

In some implementations, the operation 6152 for forming the first GLS structure segment 2131 can include depositing a first spacer sub-layer 2112 on an inner wall of the first trench 960 and filling the first trench 960 with a filling material to form a first conductive wall 2113. The first spacer sub-layer 2112 can be deposited using atomic layer deposition (ALD) or chemical vapor deposition (CVD) to achieve a uniform and conformal coating on the inner wall of the trench. After depositing the first spacer sub-layer 2112, the first trench 960 can be filled with a conductive material, such as doped polysilicon, silicides, tungsten, aluminum, copper, and/or combinations thereof, etc., to form the first conductive wall 2113. The filling process can be carried out using low-pressure chemical vapor deposition (LPCVD) or electroplating, or other deposition techniques, depending on the selected material. After filling, a planarization step, such as chemical mechanical polishing (CMP), may be performed to ensure the surface of the first conductive wall 2113 is flush with surrounding layers, completing the formation of the first GLS structure segment 2131.

In some implementations, the operation 6153 for forming the second GLS structure segment 2132 can include depositing a second spacer sub-layer 2114 on an inner wall of the second trench 1560 and filling the second trench 1560 with a filling material to form a second conductive wall 2115. The second spacer sub-layer 2114 can be deposited using atomic layer deposition (ALD) or chemical vapor deposition (CVD) to achieve a uniform and conformal coating on the inner wall of the trench. After depositing the second spacer sub-layer 2114, the second trench 1560 can be filled with a conductive material, such as doped polysilicon, silicides, tungsten, aluminum, copper, and/or combinations thereof, etc., to form the second conductive wall 2115. The filling process can be carried out using low-pressure chemical vapor deposition (LPCVD) or electroplating, or other deposition techniques, depending on the selected material. After filling, a planarization step, such as chemical mechanical polishing (CMP), may be performed to ensure the surface of the second conductive wall 2115 is flush with surrounding layers, completing the formation of the second GLS structure segment 2132.

In some implementations, depositing the second insulating layer 2111, the first spacer sub-layer 2112, and the second spacer sub-layer 2114 can be performed simultaneously. This simultaneous deposition may be achieved by using the same deposition technique (e.g., CVD or ALD) and processing conditions, allowing for efficient integration of these layers into the structure. Such simultaneous deposition can streamline the manufacturing process by reducing the number of individual deposition steps, thereby improving throughput and minimizing potential misalignment issues between the spacer sub-layers and insulating layers.

In some implementations, forming the first conductive wall 2113 and forming the second conductive wall 2115 can be performed simultaneously. This simultaneous formation can be achieved by depositing the same conductive material, such as doped polysilicon, silicides, tungsten, aluminum, copper, and/or combinations thereof, etc., into both the first trench 960 and the second trench 1560 at the same time. Techniques such as low-pressure chemical vapor deposition (LPCVD) or electroplating can be used to ensure uniform filling of both trenches. After the deposition, a single planarization step, such as chemical mechanical polishing (CMP), can be performed to ensure that both conductive walls are leveled with the surrounding structures, reducing process complexity and improving manufacturing efficiency. This simultaneous formation helps streamline the fabrication process, ensuring consistency in the conductive properties of the first and second GLS structure segments.

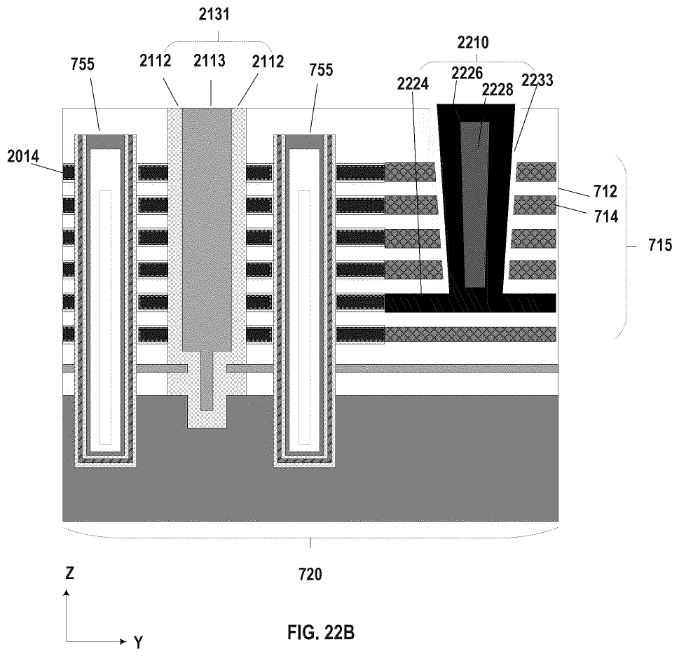

In some implementations, the method may further include forming a plurality of gate line contact structures in the stack structure in the contact region. FIG. 22A illustrates a schematic diagram of the 3D structure after removing a subset of dummy channel structures and forming a plurality of gate line contact structures in a top-down perspective view, according to some implementations of the present disclosure. FIG. 22B illustrates a schematic diagram of a portion of the 3D structure in a cross-sectional side view along the AA′ line shown in FIG. 15A, according to some implementations of the present disclosure.

As shown in FIGS. 22A and 22B, a plurality of gate line contact structures 2210 can be formed in the stack structure 715 in the contact region 720. In some implementations, forming the gate line contact structures 2210 can include forming a plurality of contact holes in the stack structure 715 in the contact region 720. In some implementations, the plurality of contact holes can each penetrate through an upper portion of the stack structure 715 in the contact region 720 and stop at one corresponding nitride layer 714. For example, one or more suitable etching processes, e.g., dry etch and/or wet etch, can be performed to remove portions of the stack structure 715 in the contact region 720 to form the plurality of contact holes. A mask layer (not show) can be used to control the shape of the contact holes during the etching process, and various etching times can be controlled to form the plurality of contact holes with different depths.

In some implementations, dielectric filling structure can be formed to fill each contact hole by any suitable deposition process. A punch etching can be performed to remove a portion of the dielectric filling structure to expose a corresponding one nitride layer 714 at the bottom of each contact hole. The remaining portion of the dielectric filling structure forms a spacer layer 2233 on the sidewall of each contact hole. A portion of the exposed nitride layer 714 can be removed by any suitable etching process to lateral expose one corresponding conductive layer 2014 at a same level of the corresponding one nitride layer 714.

A conductive layer (including 2224 and 2226) can be formed by any suitable thin film deposition process using a first conducive material to cover the spacer layer 2233 and the bottom surface of each contact hole, and in contact with the one corresponding conductive layer 2014 in a lateral direction. In some implementations, a second conductive material can then be filled in the contact holes to form a conductive filling structure 2228. The first and second conductive materials can be deposited into the contact holes using any suitable deposition method such as CVD, PVD, PECVD, sputtering, MOCVD, and/or ALD. In some implementations, the conductive layer (including 2224 and 2226), and the conductive filling structure 2228 can include any suitable conductive material, e.g., tungsten, aluminum, copper, cobalt, or any combination thereof.

The conductive layer 2226 and the conductive filling structure 2228 can form a conductive via isolated from other conductive layers 2014 by the spacer layer 2233. That is, the gate line contact structure 2210 can include a conductive via (including 2226 and 2228) and a landing conductive layer 2224. The landing conductive layers 2224 can each be laterally in contact with a corresponding conductive layer 2014. The conductive via is in direct contact with the landing conductive layer 2224, and is electrically connected to the corresponding conductive layer 2014. As such, the formed gate line contact structures 2210 can be used as word line contacts.

The foregoing description of the specific implementations will so fully reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A memory device, comprising:
a stack structure comprising an array region and a contact region located on a side of the array region in a first lateral direction; and
a gate line slit (GLS) structure extending vertically through the stack structure and laterally along the first lateral direction, comprising:
a dielectric structure extending vertically through the stack structure and located at a boundary between the array region and the contact region;
a first GLS structure segment laterally extending from the dielectric structure to the contact region along the first lateral direction; and
a second GLS structure segment laterally extending from the dielectric structure to the array region along the first lateral direction,
wherein the dielectric structure separates the first GLS structure segment and the second GLS structure segment, a first dimension of the dielectric structure in the first lateral direction is less than a second dimension of the dielectric structure in a second lateral direction perpendicular to the first lateral direction.

2. The memory device of claim 1, wherein:
the first GLS structure segment comprises a first filling wall sandwiched between first spacer layers along the second lateral direction; and
the second GLS structure segment comprises a second filling wall sandwiched between second spacer layers along the second lateral direction.

3. The memory device of claim 2, wherein the dielectric structure is a single oxide layer having the first dimension in the first lateral direction greater than a summation of a first thickness of the first spacer layer in the second lateral direction and a second thickness of the second spacer layer in the second lateral direction.

4. The memory device of claim 2, wherein the dielectric structure is a composite structure, comprising:
an intermedia sub-layer having a first material;
a first spacer sub-layer between the intermedia sub-layer and the first GLS structure segment, and having a second material different from the first material but same as the first spacer layers of the first GLS structure segment; and
a second spacer sub-layer between the intermedia sub-layer and the second GLS structure segment, and having a third material different from the first material but same as the second spacer layers of the second GLS structure segment.

5. The memory device of claim 4, wherein:
the first material is an oxide material; and
the second material and the third material are same and deposited on both sides of the intermedia sub-layer in the first lateral direction.

6. The memory device of claim 4, wherein the intermedia sub-layer has a curved wall structure.

7. The memory device of claim 1, wherein:
sidewalls of the first GLS structure segment and the second GLS structure segment in second first lateral direction comprise curved surfaces.

8. The memory device of claim 2, wherein each of the first filling wall and the second filling wall comprises an upper portion and a lower portion, wherein a dimension of the upper portion is greater than a dimension of the lower portion along the second lateral direction.

9. The memory device of claim 8, wherein:
the lower portion of the first filling wall comprises:
protruding portions each having a lateral surface and a bottom surface surrounded by the first spacer layers from all lateral directions and a bottom direction; and
the lower portion of the second filling wall comprises:
protruding portions each having a lateral surface and a bottom surface surrounded by the second spacer layers from all lateral directions and a bottom direction.

10. The memory device of claim 9, wherein:
a first height of first protruding portions of the first filling wall in a vertical direction is greater than a second height of second protruding portions of the second filling wall in the vertical direction.

11. The memory device of claim 10, further comprising a semiconductor layer located between the stack structure and a substrate, wherein:
a top surface of the semiconductor layer that is lower than a bottom surface of the upper portion of the first filling wall; and
a bottom surface of the semiconductor layer is higher than a bottom surface of the upper portion of the second filling wall.

12. The memory device of claim 11, wherein the first protruding portions and second protruding portions vertically extend into an upper portion of the substrate.

13. The memory device of claim 11, wherein the semiconductor layer in the contact region comprises:
ends extended into the second spacer layers; and
separated portions between the first protruding portions and each having a lateral surface, a bottom surface and a top surface surrounded by the first spacer layers from all lateral directions, the bottom direction and a top direction.

14. A method for forming a memory device, comprising:
forming a stack structure comprising an array region and a contact region located on a side of the array region in a first lateral direction; and
forming a gate line slit (GLS) structure extending vertically through the stack structure and laterally along the first lateral direction, comprising:
forming a dielectric structure extending vertically through the stack structure and located at a boundary between the array region and the contact region;
forming a first GLS structure segment laterally extending from the dielectric structure to the contact region along the first lateral direction; and
forming a second GLS structure segment laterally extending from the dielectric structure to the array region along the first lateral direction,
wherein the dielectric structure separates the first GLS structure segment and the second GLS structure segment, a first dimension of the dielectric structure in the first lateral direction is less than a second dimension of the dielectric structure in a second lateral direction perpendicular to the first lateral direction.

15. The method of claim 14, wherein forming the stack structure comprises:
forming an insulating layer on a substrate;
forming a semiconductor layer on the insulating layer;
forming alternately stacked first dielectric layers and second dielectric layers along a vertical direction on the semiconductor layer; and
forming an array of first through holes in the contact region and an array of second through holes in the array region, wherein each first through hole and each second through hole is vertically extending through the stack structure into the substrate.

16. The method of claim 15, wherein forming the GLS structure comprises:
forming a first trench extending along the first lateral direction by etching one row of the array of first through holes;
removing portions of the second dielectric layers located at the contact region through the first trench to form first gaps;
filling the first trench and the first gaps with a sacrificial material;
forming a second trench extending along the first lateral direction by etching one row of the array of second through holes;
removing portions of the second dielectric layers located at the array region through the second trench to form second gaps;
removing the sacrificial material from the first trench and the first gaps;
filling the first gaps and the second gaps with a conductive material; and
forming the first GLS structure segment in the first trench and forming the second GLS structure segment in the second trench.

17. The method of claim 16, wherein after forming the first trench, the method further comprises:
enlarging the first trench by removing portions of the first dielectric layer and the second dielectric layer exposed by the first trench; and
oxidizing the semiconductor layer and the substrate exposed by the enlarged first trench.

18. The method of claim 17, wherein after forming the second trench, the method further comprises:
enlarging the second trench by removing potions of the first dielectric layer and the second dielectric layer exposed by the second trench;
removing portions of the semiconductor layer and the sacrificial material exposed by the enlarged second trench; and
oxidizing a side surface of the sacrificial material in the first trench to form an intermedia sub-layer composed of a first material, wherein the side surface of the sacrificial material in the first trench is exposed by the enlarged second trench.

19. The method of claim 18, wherein filling the first trench and the first gaps with the sacrificial material comprises:
filling the first trench and the first gaps with a sacrificial semiconductor material.

20. A memory device, comprising:
a memory array; and
a peripheral circuit disposed on at least one side of the memory array,
wherein the memory array comprises:
a stack structure comprising an array region and a contact region located on a side of the array region in a first lateral direction; and
a gate line slit (GLS) structure extending vertically through the stack structure and laterally along the first lateral direction, comprising:
a dielectric structure extending vertically through the stack structure and located at a boundary between the array region and the contact region;
a first GLS structure segment laterally extending from the dielectric structure to the contact region along the first lateral direction; and
a second GLS structure segment laterally extending from the dielectric structure to the array region along the first lateral direction,
wherein the dielectric structure separates the first GLS structure segment and the second GLS structure segment, a first dimension of the dielectric structure in the first lateral direction is less than a second dimension of the dielectric structure in a second lateral direction perpendicular to the first lateral direction.
